(19) United States
(12) Patent Application Publication
(10) Pub. No.: US 2023/0377903 A1
(43) Pub. Date: Nov. 23, 2023

(54) METHOD FOR TUNING ELECTRICAL PROPERTIES OF OXIDE SEMICONDUCTORS AND THE DEVELOPMENT OF HIGHLY CONDUCTIVE P-TYPE AND N-TYPE Ga2O3

(71) Applicant: Bowling Green State University, Bowling Green, OH (US)

(72) Inventor: Farida Selim, Bowling Green, OH (US)

(73) Assignee: Bowling Green State University, Bowling Green, OH (US)

(21) Appl. No.: 17/616,023

(22) PCT Filed: Apr. 9, 2020
(86) PCT No.: PCT/US2020/027384

§ 371 Date: Dec. 2, 2021

Related U.S. Application Data
(60) Provisional application No. 62/858,092, filed on Jun. 6, 2019.

(51) Int. Cl. H01L 21/383; H01L 29/24; H01L 29/04

(52) U.S. Cl. CPC H01L 21/383; H01L 29/24; H01L 29/04

(57) ABSTRACT

A method for bipolar doping of oxide semiconductor materials, a method for doping an oxide semiconductor material n-type, a method for doping an oxide semiconductor material p-type, and products of the same are described. Also described is p-type Ga₂O₃ having hydrogen atoms as dopants. Also described is n-type Ga₂O₃ having hydrogen atoms as dopants, or having both of a sheet carrier concentration of at least about 10¹⁶ cm², and/or a mobility of at least about 100 cm²/VS at room temperature.

### RELATED APPLICATIONS

This application claims priority to U.S. Provisional Application No. 62/858,092 filed under 35 U.S.C. § 111(b) on Jun. 6, 2019, the disclosure of which is incorporated herein by reference in its entirety.

### STATEMENT REGARDING FEDERALLY SPONSORED RESEARCH

This invention was made with no government support. The government has no rights in this invention.

### BACKGROUND

Ga₂O₃ is a desirable material for many high power devices and optoelectronic applications. However, p-type Ga₂O₃ has not been reported and is considered to be a big challenge in the art. There is currently no known method for making p-type Ga₂O₃ or highly conductive n-type Ga₂O₃, despite such materials being highly desired for certain types of devices. It would be advantageous to develop p-type Ga₂O₃ and highly conductive n-type Ga₂O₃, and to develop new and improved methods for producing the same.

### SUMMARY

Provided is a composition comprising an oxide semiconductor material with a cation vacancy filled with hydrogen. In certain embodiments, the oxide semiconductor material comprises a (H—V_{Ca})¹⁻ complex, wherein Ca is the cation, and wherein the oxide semiconductor material has p-type conductivity. In certain embodiments, the oxide semiconductor material comprises a (H—V_{Ca})⁺ complex, wherein Ca is the cation, and wherein the oxide semiconductor material has n-type conductivity. In certain embodiments, the oxide semiconductor material comprises Ga₂O₃.

Further provided is a composition comprising p-type Ga₂O₃. In certain embodiments, the p-type Ga₂O₃ comprises hydrogen atoms as dopants. In particular embodiments, the hydrogen atoms are in Ga vacancies in the p-type Ga₂O₃. Also provided are power devices and optoelectronic devices comprising the composition.

Further provided is a composition comprising n-type Ga₂O₃, wherein the n-type Ga₂O₃ comprises hydrogen atoms as dopants. In certain embodiments, the n-type Ga₂O₃ has a crystal structure having 4 hydrogen atoms in Ga vacancies. In certain embodiments, the n-type Ga₂O₃ has a sheet carrier concentration of at least about 10¹⁶ cm². In certain embodiments, the n-type Ga₂O₃ has a mobility of at least about 100 cm²/VS at room temperature. Also provided are optoelectronic devices and power devices comprising the composition.

Further provided is a composition comprising n-type Ga₂O₃, wherein the n-type Ga₂O₃ has both of: a sheet carrier concentration of at least about 10¹⁶ cm², and a mobility of at least about 100 cm²/VS at room temperature. In certain embodiments, the n-type Ga₂O₃ has a resistivity of about 10⁴ Ω·cm. In certain embodiments, the n-type Ga₂O₃ comprises hydrogen atoms as dopants. Also provided are optoelectronic devices comprising the composition. In certain embodiments, the composition is a thin film having a thickness ranging from about 100 nm to about 900 nm. In certain embodiments, the composition is a thin film having a thickness ranging from about 200 nm to about 700 nm. In particular embodiments, the composition is a thin film having a thickness of about 500 nm. Also provided are optoelectronic devices and power devices comprising the composition.

Further provided is an optoelectronic device or power device comprising a p-n junction formed from p-type Ga₂O₃ and n-type Ga₂O₃. In certain embodiments, the p-type Ga₂O₃ comprises hydrogen atoms as dopants. In certain embodiments, the n-type Ga₂O₃ comprises hydrogen atoms as dopants. In certain embodiments, both the p-type Ga₂O₃ and the n-type Ga₂O₃ comprise hydrogen atoms as dopants. In certain embodiments, the n-type Ga₂O₃ has at least one of a sheet carrier concentration of at least about 10¹⁶ cm², or a mobility of at least about 100 cm²/VS at room temperature. In certain embodiments, the n-type Ga₂O₃ has a resistivity of about 10⁴ Ω·cm. In certain embodiments, the power device is high power diode, switch, or transistor, or the optoelectronic device is a photodiode, a phototransistor, a photomultiplier, an optoisolator, an integrated optical circuit element, a photoresistor, a charge-coupled imaging device, a light-emitting diode (LED), an organic light-emitting diode (OLED), a solar blind UV detector, a gas sensor, a photodetector, a power transistor, or a solar cell.

Further provided is a method of bipolar doping, the method comprising either partially filling cation vacancies in an oxide semiconductor material with hydrogen, thereby lowering their acceptor states to act as shallow acceptors, so as to dope the oxide semiconductor material p-type; or filling the cation vacancies with hydrogen plus an extra H-ion, so as to dope the oxide semiconductor material n-type.

Further provided is a method for doping an oxide semiconductor material p-type, the method comprising placing an oxide semiconductor material in a sealed system; evacuating air from the sealed system; introducing hydrogen gas into the sealed system; and annealing the oxide semiconductor material in the sealed system at an elevated temperature for a period of time to allow the hydrogen gas to diffuse into the oxide semiconductor material and thereby dope the oxide semiconductor material p-type.

In certain embodiments, the period of time is at least about 1 hour. In certain embodiments, the period of time is from about 1 hour to about 5 hours. In certain embodiments, the period of time is from about 1 hour to about 2 hours. In certain embodiments, the elevated temperature ranges from about 310° C. to about 1,000° C. In certain embodiments, the elevated temperature ranges from about 350° C. to about 1,000° C. In certain embodiments, the elevated temperature ranges from about 700° C. to about 950° C. In certain embodiments, the elevated temperature is about 950° C. In certain embodiments, the sealed system is at a pressure of less than 1 atm during the annealing. In certain embodiments, the sealed system is at a pressure ranging from about 300 torr to about 700 torr during the annealing. In certain embodiments, the sealed system is at a pressure ranging from about 500 torr to about 650 torr during the annealing. In certain embodiments, the sealed system is at a pressure of about 580 torr during the annealing. In certain embodiments, the elevated temperature is about 950° C. and the period of time is about 2 hours. In certain embodiments, the oxide semiconductor material comprises Ga₂O₃. In certain embodiments, the elevated temperature is about 950° C., the period of time is about 2 hours, the oxide semiconductor material comprises Ga₂O₃, and the sealed system is at a pressure of about 580 torr during the annealing.

Further provided is a method for doping an oxide semiconductor material n-type, the method comprising annealing an oxide semiconductor material in air for a first period of time at a first temperature; placing the oxide semiconductor material in a sealed system; evacuating air from the sealed system; introducing hydrogen gas into the sealed system; and annealing the oxide semiconductor material in the sealed system at a second elevated temperature for a second period of time to allow the hydrogen gas to diffuse into the oxide semiconductor material and thereby dope the oxide semiconductor material n-type.

In certain embodiments, the first period of time is at least about 1 hour. In certain embodiments, the first period of time ranges from about 1 hour to about 5 hours. In certain embodiments, the first period of time ranges from about 1 hour to about 2 hours. In certain embodiments, the first temperature ranges from about 310° C. to about 1,000° C. In certain embodiments, the first temperature ranges from about 350° C. to about 1,000° C. In certain embodiments, the first temperature ranges from about 700° C. to about 950° C. In certain embodiments, the first temperature is about 950° C. In certain embodiments, the second period of time is at least about 1 hour. In certain embodiments, the second period of time ranges from about 1 hour to about 5 hours. In certain embodiments, the second period of time ranges from about 1 hour to about 2 hours. In certain embodiments, the second period of time is about 2 hours. In certain embodiments, the second temperature ranges from about 310° C. to about 1,000° C. In certain embodiments, the second temperature ranges from about 350° C. to about 1,000° C. In certain embodiments, the second temperature ranges from about 700° C. to about 950° C. In certain embodiments, the second temperature is about 950° C. In certain embodiments, the sealed system is at a pressure of less than 1 atm during the annealing. In certain embodiments, the sealed system is at a pressure of from about 400 torr to about 700 torr during the annealing. In certain embodiments, the sealed system is at a pressure of from about 500 torr to about 650 torr during the annealing. In certain embodiments, the sealed system is at a pressure of about 580 torr during the annealing. In certain embodiments, the oxide semiconductor material comprises Ga₂O₃. In certain embodiments, the second period of time is about 2 hours, the second temperature is about 950° C., the oxide semiconductor material comprises Ga₂O₃, and the sealed system is at a pressure of about 580 torr during the annealing. In certain embodiments, the oxide semiconductor material comprises Ga₂O₃, the first period of time is about 2 hours, the first temperature is about 950° C., the second period of time is about 2 hours, and the second temperature is about 950° C., and the sealed system is at a pressure of about 580 torr during the annealing.

In some embodiments of the methods described herein, hydrogen plasma is used in a plasma reactor instead of annealing or diffusion of molecular hydrogen, at lower temperature or at any range of temperature, any range of pressure, and for any period of time.

Further provided are the products of any of the methods described herein.

Further provided is the use of hydrogen to dope an oxide semiconductor material n-type or p-type, without further dopants.

### BRIEF DESCRIPTION OF THE DRAWINGS

The patent or application file may contain one or more drawings executed in color and/or one or more photographs. Copies of this patent or patent application publication with color drawing(s) and/or photograph(s) will be provided by the U.S. Patent and Trademark Office upon request and payment of the necessary fees.

FIG. 1: Graph showing the theoretical ideal performance limits of β-Ga₂O₃ power devices against other major semiconductors.

FIGS. 2A-2D: Schematic diagrams showing hydrogen incorporation in β-Ga₂O₃. FIG. 2A shows hydrogen molecules coming in contact with the surface at elevated temperature and dissociating heterolytically. The electron cloud of H₂ is attracted toward gallium while the proton is attracted toward oxygen. FIG. 2B shows the proton and hydride ion are attached to oxygen and gallium atoms, respectively, on the crystal surface and diffuse through the bulk crystal at high temperatures. The proton is attracted toward the negatively charged gallium vacancy. FIG. 2C shows a Ga vacancy decorated with two hydrogen as provided from DFT calculations. FIG. 2D shows a Ga vacancy decorated with four hydrogens as provided from DFT calculations.

FIGS. 3A-3D: Sheet resistance (FIG. 3A) and sheet number (FIG. 3B) of β-Ga₂O₃ samples after several treatments. The first set 1, 2, 3, 4, 5: 1-as-grown β-Ga₂O₃ single crystal; 2-annealed in H₂; 3-annealed in H₂ after 4 days; 4-annealed in H₂ 2^{nd} time; 5-annealed in H₂ 2^{nd} time, after 4 days (this H-diffusion at 700° C. for 1 hr led to p-type conductivity that decays with time); the second set a, b, c: a-as-grown β-Ga₂O₃ single crystal; b-annealed in H₂ immediately after annealing; c-annealed in H₂ 4 days after annealing (this H-diffusion at 950° C. for 2 hrs led to p-type conductivity that is stable over time because it allows H⁺ to diffuse deeper into the crystal). Black squares—annealed at 700° C. for one hour; Red circles-annealed at 950° C. for two hours. FIG. 3C shows sheet resistance, and FIG. 3D shows sheet number, of samples; the third set 1, 2, 3: 1-as-grown 3-Ga₂O₃ single crystal; 2-annealed in O₂; 3-annealed in O₂ followed by H₂ diffusion (black square) (O-annealing led to an increase in resistivity, then the subsequent H-diffusion led to high n-type conductivity that is stable with time); the fourth set a, b: a-as-grown 3-Ga₂O₃ single crystal; b-annealed in Ga followed by H₂ diffusion (red circle) (annealing in Ga followed by H-diffusion did not induce significant changes).

FIGS. 4A-4C: Thermally stimulated luminescence emission (FIG. 4A) of the samples annealed at 950° C. for two hours in different environments. Data points for annealed samples were normalized from 0 to 1. Data points for as-grown sample were normalized from 0 to 0.5 to minimize noise (no glow peak). Peaks were fitted with a Gaussian function. The two peaks appeared at low temperature after H₂ diffusion, and after O-anneal followed by H-diffusion are associated with the induced shallow acceptor and shallow donor in the samples, respectively, and they were used for calculating the ionization energies. FIG. 4B shows the flat band diagrams showing donor and acceptor states of the samples after direct hydrogen diffusion, and FIG. 4C shows hydrogen diffusion after filling up oxygen vacancies.

FIGS. 5A-5D: Evidence of formation of shallow acceptors and shallow donors from hydrogen doping of Ga₂O₃. FIG. 5A shows defect parameters S and W measured by Doppler Broadening of Positron Annihilation Spectroscopy (DBPAS) as a function of penetration depth, S and W are defined as the fraction of positrons annihilating with valence and core electrons respectively. The lower x-axis represents the positron energies and the upper x-axis represents the penetration depth. The graph shows that H₂ diffuses about 500 nm in the crystal. Positron Annihilation Lifetime Spectroscopy (PALS) data of as-grown (FIG. 5B) and annealed in H₂ (950° C. for 2 hours) (FIG. 5C), annealed in O₂ followed by H₂ (950° C. for 2 hours) (FIG. 5D) samples. E_{P}=Positron implantation energy, Zₘₑₐₙ=positron implantation depth, τ=positron lifetime, I=intensity of lifetime component, the graphs b, c, and d show the two positron lifetime components and their intensities in each sample.

FIGS. 6A-6B: Schematic diagram of thermoluminescence process for donor (FIG. 6A) and acceptor (FIG. 6B) cases.

FIGS. 7A-7B: Calculation of ionization energy by initial rise method. Linear fitting of ln (I) vs. 1/T of β-Ga₂O₃ sample annealed in oxygen followed by hydrogen diffusion (FIG. 7A) and hydrogen diffused β-Ga₂O₃ sample (FIG. 7B).

FIG. 8: Positron lifetime spectra at Eₚ=6 keV for the H₂ diffused sample and the sample annealed in O₂ followed by H₂ diffusion.

FIGS. 9A-9D: Temperature dependent transport properties of the n-type and p-type H₂ treated p-Ga₂O₃ samples. FIG. 9A shows sheet resistance. FIG. 9B shows sheet number. FIG. 9C shows sheet number logarithm plotted as a function of 1000/T. FIG. 9D shows the dependence of n-type mobility on temperature.

FIG. 10: X-ray diffraction (XRD) measurements of as-grown sample, H-diffused p-type sample, and O-annealed H-diffused n-type sample.

FIGS. 11A-11C: TSL glow curves of as-grown (FIG. 11A) and p-type H diffused (FIG. 11B) samples, and a diagram (FIG. 11C) illustrating the location of these levels in the band gaps.

FIGS. 12A-12B: TSL glow curves of as-grown (FIG. 12A) and n-type O-annealed H-diffused (FIG. 12B) samples, showing the deep traps in the samples. FIG. 12C shows a diagram illustrating the locations of these levels in the band gap.

FIGS. 13A-13D: Contour plots of as-grown (FIG. 13A), H-diffused (FIG. 13B), and O-annealed followed by H-diffused (FIG. 13C) samples where emission intensity is plotted as a function of temperature and wavelength. FIG. 13D shows green emission from a H-diffused p-type sample.

FIGS. 14A-14B: Photoluminescence emission and mechanisms. FIG. 14A shows PL emission of the as-grown and p-type H-diffused sample. FIG. 14B shows two diagrams; the diagram on the right illustrates the mechanism of the 380 nm UV emission, and the diagram on the left illustrates the mechanism of the broad emission (blue and green).

### DETAILED DESCRIPTION

Throughout this disclosure, various publications, patents, and published patent specifications are referenced by an identifying citation. The disclosures of these publications, patents, and published patent specifications are hereby incorporated by reference into the present disclosure in their entirety to more fully describe the state of the art to which this invention pertains.

Provided herein are methods to induce bipolar (n-type and p-type) conductivity in wide band gap oxide semiconductors and control their transport properties, simply by controlling hydrogen incorporation in the lattice. The methods can realize high carrier density while maintaining good mobility in oxide semiconductors using hydrogen instead of conventional doping methods. A shallow donor type in semiconductors may be generated by decorating a cation vacancy with hydrogen. It is shown herein that hydrogen may act as a shallow donor and may induce very high n-type conductivity in oxide semiconductors, or may act as a shallow acceptor and may include p-type conductivity in oxide semiconductors.

Wide band gap oxide semiconductors are generally difficult to dope in either direction, especially while maintaining high carrier concentration and good mobility. The present disclosure alleviates these issues, providing for wide band gap oxide semiconductors that may be doped either n-type or p-type and still have high carrier concentration and good mobility. Without wishing to be bound by theory, it is believed that the carrier concentration and mobility are not degraded because the method of inserting hydrogen ions into cation vacancies does not introduce disorder into the crystal structure. This is because the hydrogen ion is very small.

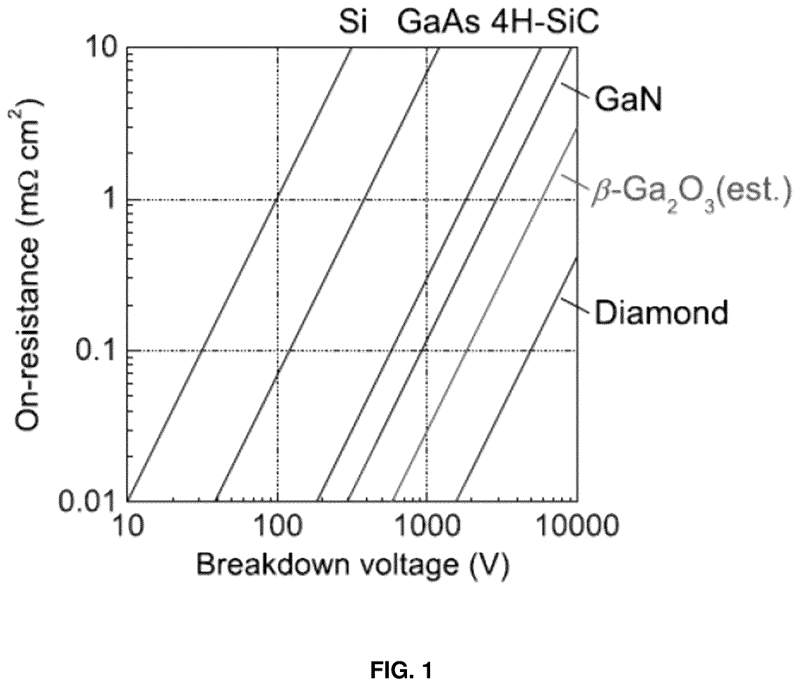

Using the methods described herein, p-type Ga₂O₃ has been developed. Furthermore, using the methods described herein, a remarkably high conductivity n-type Ga₂O₃ has been developed. As seen from FIG. 1 and Table 1, Ga₂O₃ has advantageous properties for use in high power devices and optoelectronic devices. However, the realization of p-type is important for these applications. FIG. 1 shows the theoretical ideal performance limits of R—Ga₂O₃ power devices against other major semiconductors. The following Table 1 shows material properties of major semiconductors and β-Ga₂O₃:

TABLE 1
Material properties of major semiconductors and β-Ga₂O₃.

| | Si | GaAs | 4H—SiC | GaN | diamond | β-Ga₂O₃ |
|---|---|---|---|---|---|---|
| bandgap E_{g} | 1.1 | 1.4 | 3.3 | 3.4 | 5.5 | 4.7-4.9 |
| (eV) | | | | | | |
| electron | 1400 | 8000 | 1000 | 1200 | 2000 | 300 |
| mobility μ | | | | | | |
| (cm²V⁻¹s⁻¹) | | | | | | |
| breakdown | 0.3 | 0.4 | 2.5 | 3.3 | 10 | 8 |
| field E_{b} | | | | | | |
| (MV cm⁻¹) | | | | | | |
| relative | 11.8 | 12.9 | 9.7 | 9.0 | 5.5 | 10 |
| dielectric | | | | | | |
| constant [symbol] | | | | | | |
| Baliga's FOM | 1 | 15 | 340 | 870 | 24664 | 3444 |
| [symbol] μE_{b}³ | | | | | | |
| thermal | 1.5 | 0.55 | 2.7 | 2.1 | 10 | 0.23 [010] |
| conductivity | | | | | | 0.13 [100] |
| (Wcm⁻¹K⁻¹) | | | | | | |

[symbol]

indicates data missing or illegible when filed

However, as with other wide band gap oxide semiconductors, there are challenges with doping Ga₂O₃. Doping typically reduces mobility in semiconductors, and an increase of carrier concentration by doping is usually done at the expense of the mobility. In fact, the only n-type Ga₂O₃ reported thus far does not have the very high conductivity described herein, which is important for transparent conductor applications, and there has not yet been a report of a p-type Ga₂O₃. The present disclosure provides for the production of both p-type Ga₂O₃ and high conductivity n-type Ga₂O₃. For example, the n-type Ga₂O₃ of the present disclosure may have a carrier concentration of about 10¹⁶ cm² in about several hundred nanometers of thickness and a mobility of about 100 cm²/VS at room temperature. Given its high conductivity, the n-type Ga₂O₃ described herein may be particularly useful as a transparent conductive oxide (TCO) in an optoelectronic device such as a photovoltaic device, light emitting diode (LED), or illumination devices, or in high power devices.

The present disclosure provides a different donor type in semiconductors: shallow donors by decorating a cation vacancy with hydrogen. It is shown in the examples herein that hydrogen may act as a shallow donor and may induce very high n-type conductivity in oxides. It is also shown in the examples herein that hydrogen may act as a shallow acceptor and may induce p-type conductivity in oxides. Thus, provided herein is an oxide semiconductor material with a cation vacancy filled with hydrogen. In some embodiments, the oxide semiconductor material comprises a (H—V_{Ca})¹⁻ complex, wherein Ca is the cation, and wherein the oxide semiconductor material has p-type conductivity. In some embodiments, the oxide semiconductor material comprises a (H—V_{Ca})¹⁺ complex, wherein Ca is the cation, and wherein the oxide semiconductor material has n-type conductivity. Although Ga₂O₃ is described herein for exemplary purposes, the present disclosure is by no means limited to Ga₂O₃. Rather, any oxide semiconductor material may be doped p-type or n-type with hydrogen as described herein.

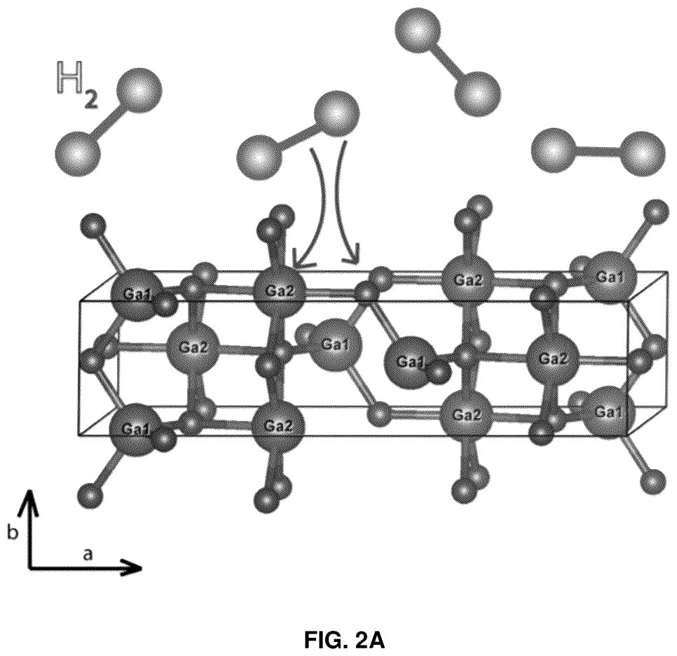

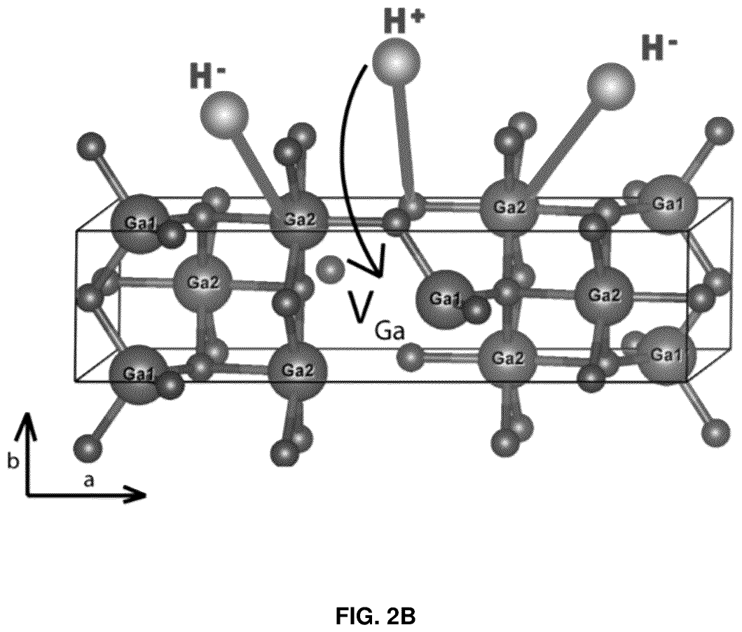

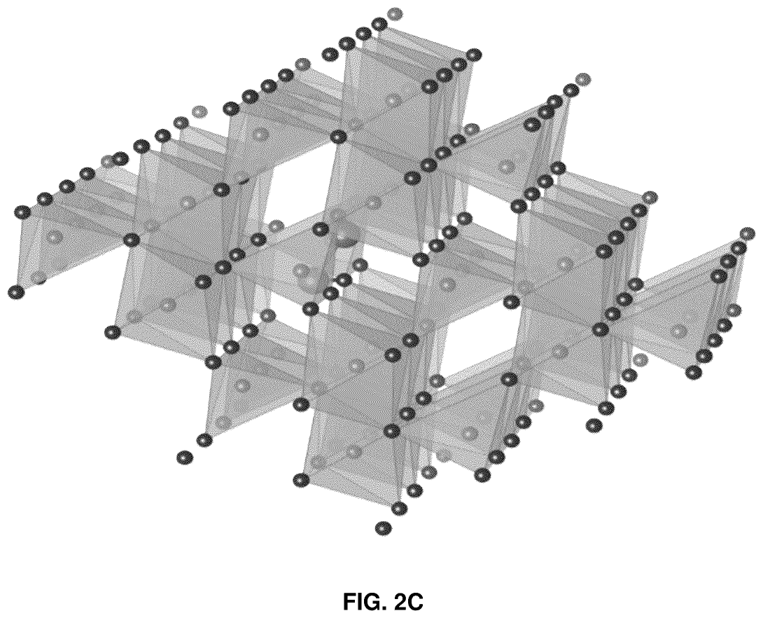

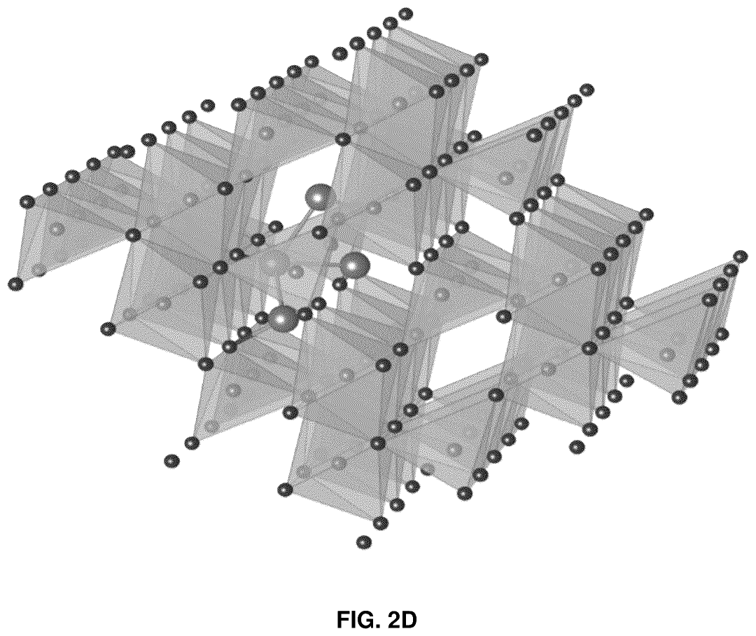

In general, bipolar doping in accordance with the present disclosure involves exposing an oxide semiconductor material to hydrogen in a sealed system, and then annealing the sealed system at an elevated temperature for a period of time so as to allow the hydrogen to diffuse into the oxide semiconductor material. When this hydrogen diffusion process is conducted without first annealing the oxide semiconductor material in air or otherwise in the presence of oxygen, the resulting oxide semiconductor material may be doped p-type. However, when the hydrogen diffusion process is conducted after first annealing the oxide semiconductor material in air or otherwise in the presence of oxygen, the resulting oxide semiconductor material may be doped n-type. Without wishing to be bound by theory, it is believed that hydrogen fills cation vacancies in the oxide semiconductor material, but may also fill oxygen vacancies. When an oxygen anneal is conducted prior to the hydrogen diffusion, the oxygen vacancies in the lattice are filled first, causing the subsequent hydrogen diffusion to force more hydrogen atoms into the cation vacancies. In other words, the absence of oxygen vacancies following the oxygen annealing means that the only available traps for H⁺ are cation vacancies, which thus become filled to a greater extent, resulting in n-type conductivity. This doping can also be done by increasing the amount of diffused hydrogen (through increasing the time of diffusion or H-pressure) instead of prior O-annealing. FIGS. 2A-2D illustrate the hydrogen incorporation.

The hydrogen is generally introduced to the sealed system at a pressure below 1 atm, and the sealed system may be kept at a pressure below 1 atm, such as from about 400 torr to about 700 torr, or from about 500 torr to about 650 torr, during the annealing. In one non-limiting example, the sealed system is at a pressure of about 580 torr during the annealing. Air may be evacuated from the sealed system to create a vacuum prior to the introduction of hydrogen. The sealed system may be of any scale, for example an ampoule or a large vacuum chamber. The sealed system may be inserted into an oven or furnace, or may itself include heating elements. The size and configuration of the sealed system are not particularly limited.

As mentioned above, the hydrogen diffusion process involves annealing at an elevated temperature for a period of time. The period of time may be at least about 1 hour. In some embodiments, the period of time ranges from about 1 hour to about 5 hours, or from about 1 hour to about 2 hours. In some embodiments, the period of time is more than about 2 hours. For best results, the ideal period of time may depend on other variables such as the temperature of the annealing. For instance, at lower temperatures, a longer period of time for diffusion may be desirable.

The elevated temperature for the hydrogen diffusion annealing step is generally above 300° C. In some embodiments, the elevated temperature ranges from about 310° C. to about 1,000° C., or from about 350° C. to about 1,000° C., or from about 700° C. to about 950° C. Use of too low of a temperature may not work to adequately diffuse hydrogen. For example, at 300° C., the method may not work to successfully produce p-type Ga₂O₃. However, the elevated temperature needed for adequate diffusion of hydrogen into the lattice may depend on the amount of time allowed for diffusion and the pressure under which the sealed system is exposed to hydrogen. For example, if shorter amounts of time are used, then a higher temperature may produce better results. Also, if hydrogen plasma is used instead of gas, the doping may be carried at much lower temperatures.

As shown in the examples herein, when left for 1 hour to diffuse at an elevated temperature of 700° C. and a pressure of 580 torr, the oxide semiconductor β-Ga₂O₃ became conductive, but thereafter became resistive again after about 4 days because the diffusion reversed. However, when the hydrogen was allowed to diffuse for 2 hours at an elevated temperature of 950° C. and a pressure of 580 torr, the conductivity became permanent. Thus, the present disclosure may be utilized to provide permanent conductivity, but may also be utilized to produce temporary conductivity in an oxide semiconductor material.

When doping an oxide semiconductor material n-type, only one extra step relative to the method for doping the oxide semiconductor p-type is necessary: annealing the oxide semiconductor in air (or otherwise in the presence of oxygen) prior to exposing the oxide semiconductor material to hydrogen gas in a sealed system and subsequently annealing at an elevated temperature. Thus, when doping an oxide semiconductor material n-type, the method involves annealing an oxide semiconductor material in air or in oxygen at a first temperature for a first period of time, then exposing the oxide semiconductor to hydrogen gas in a sealed system (i.e., placing the annealed oxide semiconductor material in a sealed system, evacuating air from the sealed system, and introducing hydrogen gas to the sealed system), and then annealing the oxide semiconductor in the sealed system with hydrogen gas at a second temperature for a second period of time. In this method, the second temperature is equivalent to the elevated temperature discussed above, and the second period of time is equivalent to the period of time discussed above (with respect to doping an oxide semiconductor p-type). However, the first temperature and the first period of time may be different from the second temperature and the second period of time, respectively, or may be the same. In some embodiments, the first period of time is at least about 1 hour. In some embodiments, the first period of time ranges from about 1 hour to about 5 hours, or from about 1 hours to about 2 hours. In some embodiments, the first temperature ranges from about 310° C. to about 1,000° C., or from about 350° C. to about 1,000° C., or from about 700° C. to about 950° C. In certain embodiments, the first temperature is about 950° C. The pressure of the sealed system during the annealing with hydrogen may be equivalent to that of the method for doping an oxide semiconductor p-type.

The products of the methods described herein are highly advantageous because they may be, for example, transparent conductive oxides with high carrier concentration and good mobility. As mentioned, the methods have been utilized to make stable p-type Ga₂O₃, and to make n-type Ga₂O₃ that may have a sheet carrier concentration of at least about 10¹⁶ cm², or may have a mobility of at least about 100 cm²/VS at room temperature. Each of these compositions may be utilized in optoelectronic devices. Moreover, both p-type Ga₂O₃ and n-type Ga₂O₃ may be utilized to create a p-n junction in a device such as an optoelectronic device. Thus, in addition to the stable p-type Ga₂O₃, and n-type Ga₂O₃ that may have a sheet carrier concentration of at least about 10¹⁶ cm² and/or a mobility of at least about 100 cm²/VS at room temperature, further provided herein are Ga₂O₃-based devices having p-n junctions formed from p-type Ga₂O₃ and n-type Ga₂O₃ (which may or may not be the highly conductive Ga₂O₃ described herein). Non-limiting examples of optoelectronic devices that the doped oxide semiconductor materials described herein may be utilized in include photodiodes, phototransistors, photomultipliers, optoisolators, integrated optical circuit elements, photoresistors, charge-coupled imaging devices, light-emitting diodes (LEDs), organic light-emitting diodes (OLEDs), solar blind UV detectors, gas sensors, photodetectors, transistors, or solar cells. Non-limiting example power devices that the doped oxide semiconductor materials described herein may be utilized in include power diodes, power switches, and power transistors.

Though Ga₂O₃ is described herein for example purposes, the methods are not limited to use with Ga₂O₃. The methods described herein may be used for bipolar doping in other wide band gap oxide semiconductors, and, in fact, may be simpler than most conventional doping methods. The methods may be implemented to dope any oxide semiconductor. Without wishing to be bound by theory, it is believed that the methods may be utilized with any oxide semiconductor because of the ease with which oxygen and hydrogen form bonds.

The bipolar doping described herein, by using only hydrogen diffusion without further doping by other elements, is quite different from conventional doping, which is generally achieved by doping with other elements during growth or after growth. In accordance with the present disclosure, hydrogen diffusion may be used to dope and induce high conductivity. Hydrogen doping may result in a higher carrier density and good mobility. Hydrogen doping may generate a shallow donor type in semiconductors. Filling cation vacancies with hydrogen ions may improve the electron mobility in semiconductors, which is useful for switching and high RF. As shown in the examples herein, this method may be used to produce p-type Ga₂O₃ as well as highly conductive n-type Ga₂O₃. The present disclosure provides for cheaper power electronics, gas sensors, MOSFETs, and the like using gallium oxide.

### Examples

Hydrogen Induced p-Type and n-Type Conductivity in an Ultra-Wide Band Gap Oxide

The future technology of optoelectronic and high-power devices is tied to the development of wide band gap materials with excellent transport properties. However, bipolar doping (n-type and p-type doping) has been a big challenge and has hindered the development of many wide band gap oxide-based devices. Standard chemical doping of elements on substitutional or interstitial sites often reduces carrier mobility and there is always a trade-off between increasing the maximum attainable carrier density and maintaining good mobility in oxides. In these examples, it is demonstrated how to produce p-type and n-type conductivity through hydrogen diffusion without further doping in an ultra-wide band gap oxide with ˜5 eV band gap energy. As shown herein, by controlling H-incorporation in the β-Ga₂O₃ lattice, it is possible to switch between p-type and n-type conductivity. An increase of 9 orders of magnitude of n-type conductivity (with donor ionization energy of 20 meV) was observed with resistivity of 10⁴ Ω·cm, sheet carrier concentration of 10¹⁶ cm⁻², and mobility of 100 cm²/VS at room temperature. The development of stable p-type Ga₂O₃ (with acceptor ionization energy of 42 meV) just by altering hydrogen incorporation in the lattice is further shown. Density functional theory calculations were used to examine hydrogen incorporation in the Ga₂O₃ lattice, supporting the interpretation of the experimental results. These examples illustrate a useful approach to manipulating the transport properties of oxide semiconductors, and may be used to develop Ga₂O₃ devices, which may significantly advance optoelectronics and high-power electronics.

A wide band gap energy has become a key parameter for the future development of high-power transistors and many optoelectronic devices, and wide band gap oxides, such as ZnO, have been shown to exhibit excellent characteristics. However, their deployment in many applications has been hindered due to the lack of conductivity control or the difficulty of realizing high carrier density with good mobility. Bipolar doping (realizing both n-type and p-type) is one of the big challenges in wide band gap materials but it is important for the development of most devices. Further, substitutional doping of elements, the most common method to provide charge carriers, often causes disorder, suppressing carrier mobility. In these examples, the inducement of p-type and n-type conductivity in an ultra-wide band gap oxide through controlling hydrogen (H) uptake in the lattice without further substitutional doping is described, and a sheet electron density of 10¹⁶ cm² with electron mobility of 100 cm² V⁻¹ S⁻¹ at room temperature is demonstrated. Such high electron density and good mobility is remarkable for oxide semiconductors. The present examples were carried out on Ga₂O₃, which is an important material for high power transistors due to its large band gap (˜4.5-5 eV) and high breakdown field of 8 MV/cm. As a transparent semiconducting oxide, Ga₂O₃ also has applications as transparent contacts in, for example, photovoltaic devices, liquid crystal displays, and light emitting diodes. β-Ga₂O₃ is the most stable polymorph of the Ga₂O₃ phases, with a monoclinic crystal structure of space group C2/m. It behaves as an insulator in its defect free crystalline form. However, intrinsic n-type conductivity originated from oxygen vacancies (V_{O}) has been described to exist, even though recent calculations have confirmed that V_{O} are deep donors in β-Ga₂O₃ and hence unlikely to be the cause of n-type conductivity. It is imperative to construct conductive β-Ga₂O₃ films for its successful incorporation into devices and many unsuccessful attempts have been made. Currently, only one type of conductivity (n-type) has been achieved by doping β-Ga₂O₃ with Sn, Ge, or Si during growth. With respect to p-type conductivity, there has not previously been any significant success by doping or annealing.

Hydrogen is known to have a strong influence on the electrical conductivity of transparent conducting oxides and semiconductors where it can give rise to shallow donors and can passivate deep compensating defects. In β-Ga₂O₃, monoatomic H has a low formation energy and can occupy both interstitial and substitutional sites to act as a shallow donor. The complex crystal structure of β-Ga₂O₃ allows for the formation of many configurations where interstitial hydrogen (Hᵢᵢ⁺) forms a bond with oxygen, creating electronic states which are close in energy. It is believed that Hᵢ acts exclusively as a shallow donor and substitutional hydrogen, H_{O}, has low formation energy only under oxygen poor conditions. Despite these theoretical predictions on the possibility of n-type conductivity due to H-incorporation in various locations, there has not been any report on significant experimental success. In the present examples, H-donors and H-acceptors are generated in Ga₂O₃ by controlling H incorporation on cation vacancy sites, not as Hᵢ or H_{O}. A cation vacancy is an electrical compensating acceptor in transparent conducting oxides and semiconductors including β-Ga₂O₃. Although cation vacancies have high formation energy in some oxide semiconductors (e.g., SnO₂, In₂O₃), previous first principle calculations showed that their formation energy is significantly lower in β-Ga₂O₃ and hence a high probability of H-decorated V_{Ga} formation can be achieved after incorporating H into the crystal.

It is important to understand the interaction of H₂ with the surface of metal-oxide semiconductors to gain insight into the process of hydrogen incorporation into the crystal. H-incorporation into the crystals at high temperature occurs in two steps. At first, H₂ dissociates and becomes attached to the surface, then diffuses into the bulk crystal. Depending on the nature of the materials, H₂ can follow either homolytic or heterolytic dissociation pathways. In the case of homolytic cleavage, the H₂ molecule dissociates to form two H-atoms that become attached to the oxygen on the crystal surface. On the other hand, H₂ dissociates to form a proton and a hydride during heterolytic cleavage where the proton and hydride become attached to the oxygen and metal atoms, respectively. The redox capacity of metals determines the type of dissociation that is most likely to occur. Density functional theory (DFT) predicts that H₂ tends to dissociate heterolytically on nonreducible oxide (e.g., MgO, γ-Al₂O₃) surfaces while following a homolytic pathway on reducible oxide (e.g., CeO₂) surfaces. p-Ga₂O₃ was found to be nonreducible via DFT. Therefore, without wishing to be bound by theory, it is most likely that H₂ follows heterolytic dissociation as shown in FIG. 2A. The adsorbed proton and hydride diffuse into the bulk crystal at high temperatures. The proton is attracted toward the negatively charged V_{Ga} while the hydride is attracted toward the positively charged or neutral V_{O}, as shown in FIG. 2B. This incorporation of hydrogen into different vacancy sites can have remarkable effects on the electrical properties of Ga₂O₃ and semiconducting oxides in general as shown in these examples.

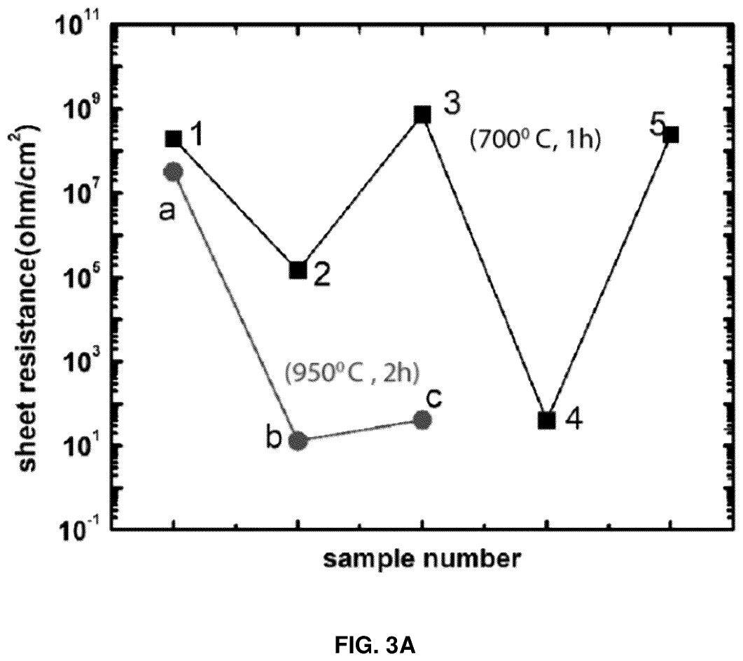

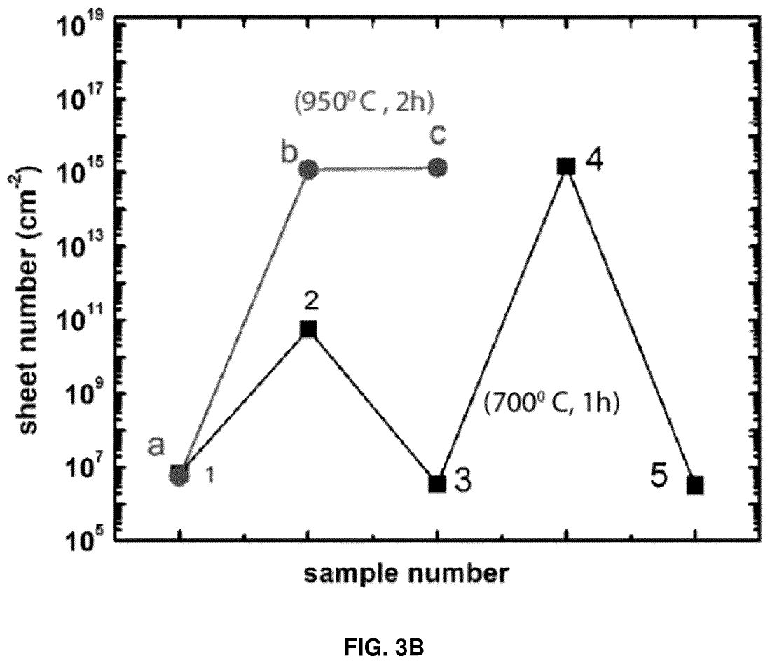

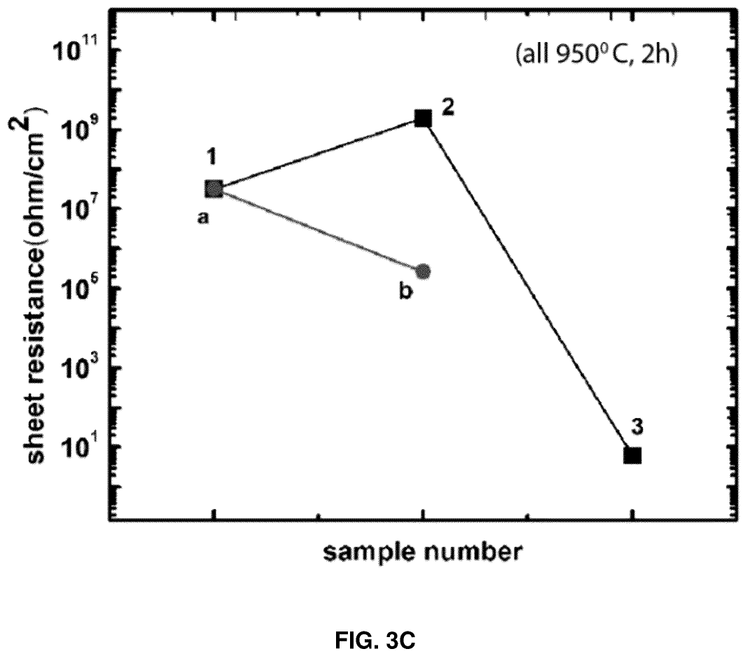

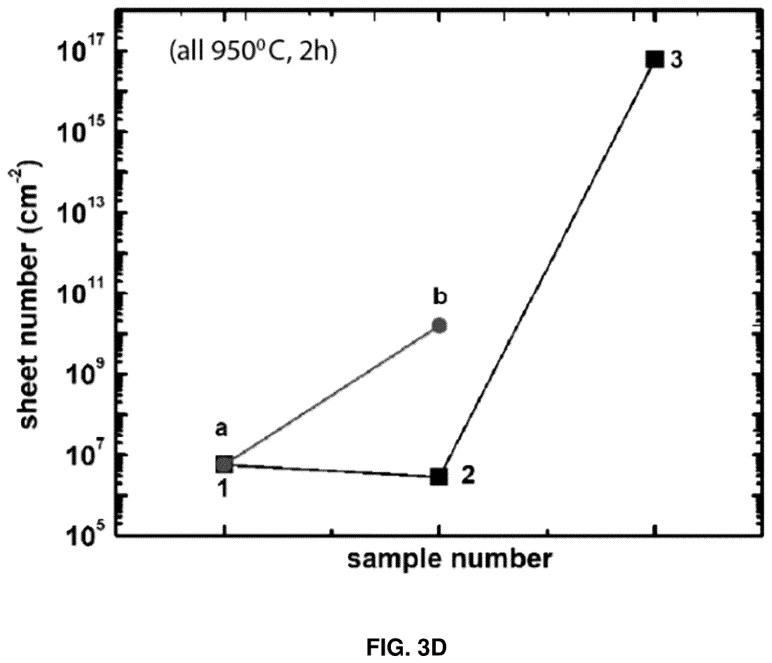

A series of experiments were carried out to incorporate H into undoped R—Ga₂O₃ single crystals. The experiments were done on samples grown by the Edge-defined Film-fed Growth method (EFG) propagating parallel to the (010) plane and cut into pieces of 5×5×0.5 mm. As-grown samples were highly resistive, but after H₂-diffusion in a closed ampoule filled only with H₂ at 580 torr, they showed an increase in carrier density and p-type conductivity. H₂-diffusion at 700° C. for 1 hr led to unstable conductivity that decays with time. However, H₂-diffusion at 950° C. for 2 hrs led to a greater increase in carrier density and stable p-type conductivity over time. Other procedures were carried out to incorporate H₂ into different sites in the undoped R—Ga₂O₃. One sample was annealed in O₂ flow and another was annealed with Ga in a closed ampoule at 950° C. for 2 hrs. This process is believed to fill up the respective (anion or cation) vacancies. After that, hydrogen was diffused into the crystals at 580 torr in a closed ampoule at 950° C. for 2 hrs. O₂-annealing followed by H₂ diffusion led to high n-type conductivity (stable over time) and remarkable sheet carrier density of about 10¹⁶ cm⁻² with electron mobility of 100 cm²/Vs. In contrast, annealing in Ga followed by H₂-diffusion did not exhibit a significant increase in conductivity. The results are summarized in Table 2 below and FIGS. 3A-3D.

TABLE 2
Transport properties of Ga₂O₃
samples and H binding energies to V_{Ga}

| | | | |
|---|---|---|---|
| sample | | sheet number | sheet resistance |
| number | sample | (cm⁻²) | (ohm/cm²) |

(a) H₂ diffusion took place in a closed
ampoule at 700° C. and 580 torr for one hour

| | | | |
|---|---|---|---|
| 1 | undoped β-Ga₂O₃ | 7.00E+06 | 1.940E+8 |
| | single crystal | | |
| 2 | annealed in H₂ | 5.45E+10 | 1.480E+5 |
| | | (p-type) | |
| 3 | annealed in H₂ | 3.44E+06 | 7.330E+8 |
| | (after 4 days) | | |
| 4 | annealed in H₂ | 1.54E+15 | 4.060E+1 |
| | (2nd time) | (p-type) | |
| 5 | annealed in H₂ | 3.24E+06 | 2.360E+8 |
| | (2nd time, after 4 days) | | |

(b) H₂ diffusion took place in a closed
ampoule at 950° C. and 580 torr for two hours

| | | | |
|---|---|---|---|
| a | undoped β-Ga₂O₃ | 5.67E+06 | 3.151E+7 |
| | single crystal | | |
| b | annealed in H₂ | 1.20E+15 | 1.288E+1 |
| | (immediately after annealing) | (p-type) | |
| c | annealed in H₂ (4 | 1.35E+15 | 4.126E+1 |
| | days after annealing) | (p-type) | |

(c) samples annealed in different environments at 950° C. for two hours
followed by H₂ diffusion at the same temperature and pressure (580 torr)

| | | | |
|---|---|---|---|
| 1 or a | as-grown undoped β- | 5.67E+06 | 3.15E+7 |
| | Ga₂O₃ single crystal | | |
| 2 | annealed in O₂ | 2.87E+06 | 1.99E+9 |
| 3 | annealed in O₂ followed | 6.14E+16 | 6.21E+0 |
| | by annealed in H₂ | (n-type) | |
| b | annealed in Ga followed | 1.55E+10 | 2.59E+5 |
| | by annealed in H₂ | | |

(d) Binding energy of H⁺ ions to a Ga vacancy. Three different values
are provided, each providing a different perspective of the interaction.
The first, the binding energy, is the value calculated by Eq. 3. The
second, the binding energy per H, is the binding energy normalized by
the number of H in the complex. Finally, the binding energy of an extra
H is the energy difference between the N and N-1 complexes, and
represents the energy released by adding the N^{th} H⁺ ion to the complex.
The net charge of the complex is also provided.

| | Net charge | | | |
|---|---|---|---|---|
| | of the H-V_{Ga} | Binding | Binding energy | Binding energy |
| N | complex | energy (eV) | per H (eV) | of extra H (eV) |
| 1 | −2 | −4.4 | −4.4 | −4.4 |
| 2 | −1 | −7.5 | −3.7 | −3.1 |
| 3 | 0 | −9.4 | −3.1 | −1.9 |
| 4 | +1 | −10.2 | −2.6 | −0.8 |

Without wishing to be bound by theory, the realization of p-type and n-type conductivity after H₂ diffusion can be explained as follows. A Ga-vacancy acts as a deep acceptor with a −3 charge state (V_{Ga})³⁻. During the diffusion of hydrogen into the crystal, the surface adsorbed proton (FIGS. 2A-2B) becomes attracted toward the (V_{Ga})³ where it stabilizes the negative charge and, therefore, lowers the acceptor state. This results in H-decorated gallium vacancy (V_{Ga}-2H)¹ (as represented in FIG. 2C) and an increase in p-type conductivity. At lower temperatures (e.g., 700° C.), protons are less likely to diffuse deep inside the bulk crystal. This results in a decrease in conductivity over time due to the reverse diffusion at room temperature. However, the high p-type conductivity persists over time for the sample exposed to H₂ at higher temperature and for a longer period of time due to the diffusion of H⁺ deeper into the crystal.

The sample that is exposed to the H₂ after filling up V_{O} (i.e., after annealing in O₂) showed high n-type conductivity. In this case, more H atoms are diffused to the V_{Ga} due to the absence of V_{O}, leading to the formation of (V_{Ga}-4H)¹⁺ (as represented in FIG. 2D), which acts as a donor. That is, the absence of V_{O} in this case means that the only available traps for H⁺ are V_{Ga}, which thus become filled to a greater extent. The contribution of n-type conductivity from interstitial hydrogen, Hᵢ, is not prominent as filling up V_{Ga} followed by H-diffusion shows a negligible increase in carrier concentration. Moreover, it confirms that the H-decorated cation vacancies are primarily responsible for the induced n-conductivity in the samples.

Density functional theory, as implemented in the Vienna ab-initio Simulation Package (VASP), was used to examine H-incorporation into a Ga-vacancy. These calculations were performed on a 1×4×2 supercell of R—Ga₂O₃, containing a total of 160 atoms in the defect-free structure. A F-centered 2×2×2 Monkhorst-Pack k-point mesh was used to sample the Brillouin zone. A V_{Ga} was created by removing a tetrahedrally-coordinated Ga ion from the cell, as this vacancy structure has been identified as being more favorable. A net charge of −3 was imposed on the structure. H⁺ ions with a charge of +1 were inserted into the resulting vacancy structure, leaving the total number of electrons in the system constant but reducing the net charge of the cell. The details of the computational method and the calculations of the binding energy for each configuration are given below. The results are presented in Table 2, (d), above. The binding energy of one H⁺ ion to the Ga vacancy is −4.4 eV. The DFT calculations reveal that, as N (the number of H ions) increases, at least up to N=4, the reaction remains exothermic, though the strength of the binding, per H atom, decreases. The energy gained by adding the 4th H⁺ ion is only −0.8 eV, much less than the −4.4 eV gained by adding the 1st H⁺ ion. If the trend persisted, this indicates that no more than 4 H⁺ ions can be favorably accommodated into V_{Ga}. Thus, these calculations indicate that a single V_{Ga} can accommodate up to 4 H⁺ ions, changing the net charge of the complex from 3− (when N=0) to 1+ (when N=4), and confirm that (V_{Ga}-4H)¹⁻ (FIG. 2D) is more favorable than H₁⁺. These calculations verified the interpretation of the electrical transport measurements that (V_{Ga}-4H)¹⁻ is the dominant donor in the treated highly conductive n-type sample.

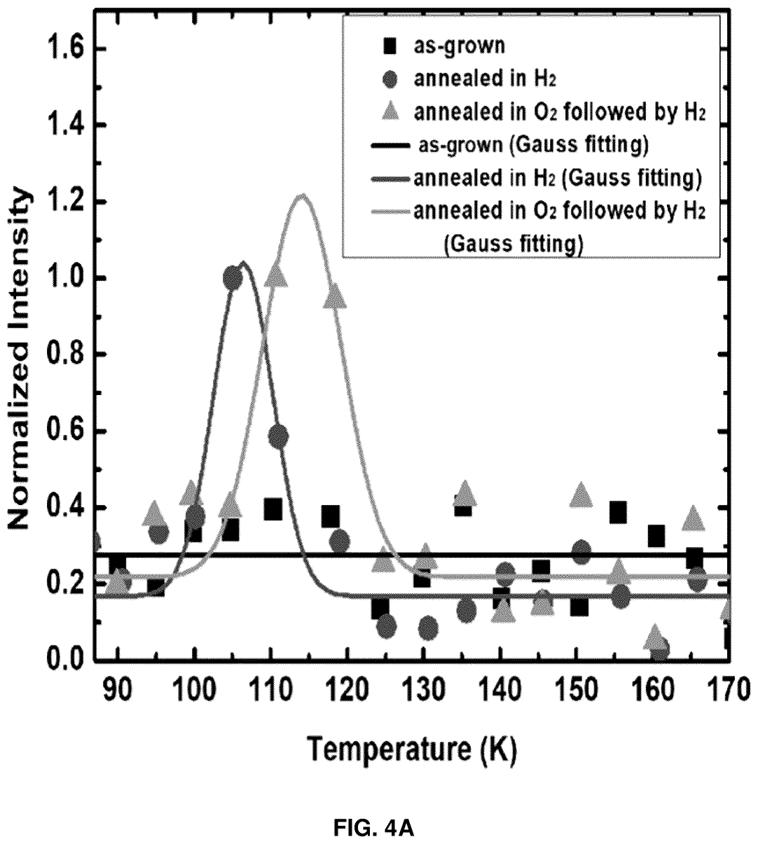

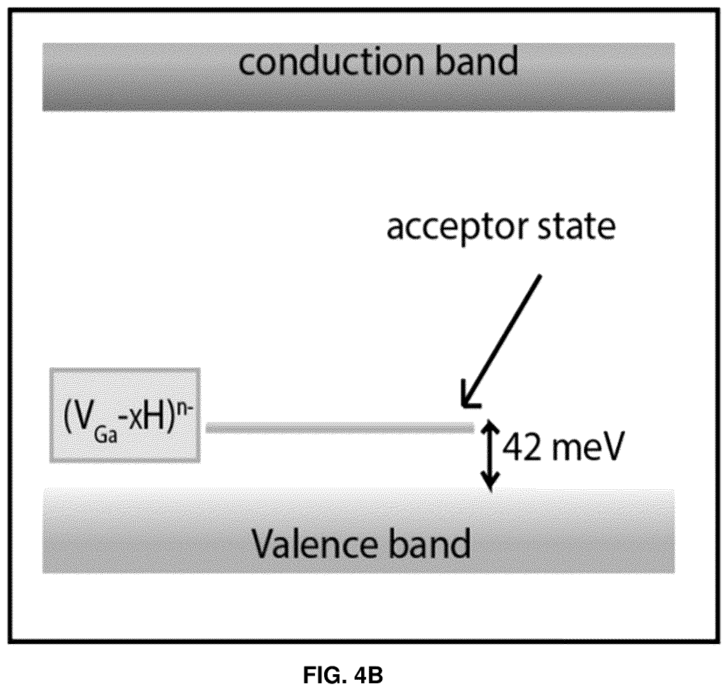

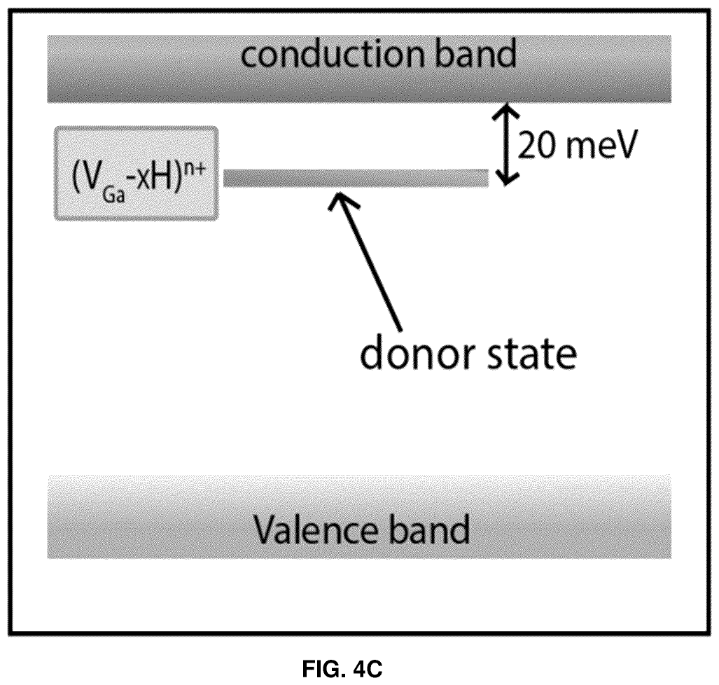

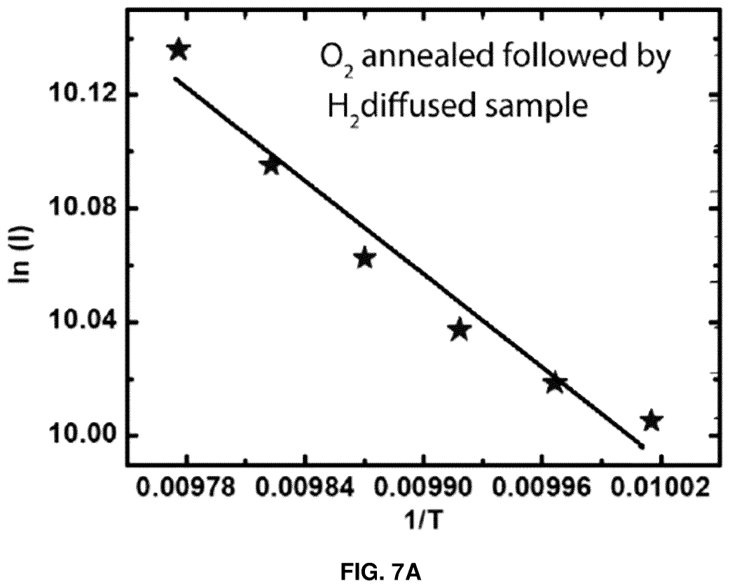

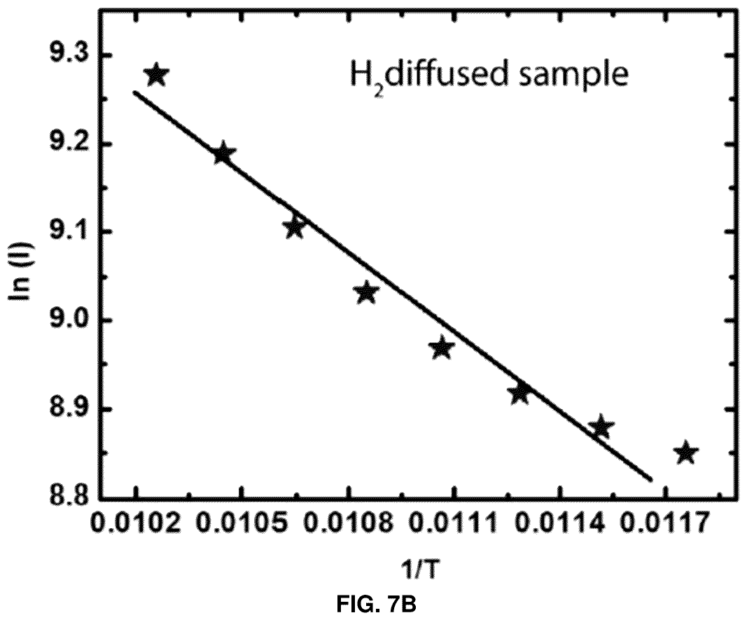

Thermal stimulated luminescence (TSL) spectroscopy was performed on the samples to calculate the donor and acceptor ionization energies. The details of the method and measurements, data analysis, and calculations of the ionization energies are explained below. FIG. 4A displays the TSL emission for as-grown, p-type, and n-type H₂ treated Ga₂O₃. The as-grown sample shows no peak corresponding to shallow levels. Each of the other two samples shows a peak at low temperature indicating the formation of shallow level. The peak formed at 107 K in the p-type H₂-anneal sample (red curve in FIG. 4A) is associated with the formation of shallow acceptors with ionization energy of 42 meV, calculated using the initial rise method (see FIG. 7). The ionization energy of the donor, emerging after O₂-annealing followed by H₂-diffusion (green curve in FIG. 4A), was also calculated by the initial rise method from the peak at 111 K and found to be 20 meV (see FIG. 7). FIGS. 4B-4C show the corresponding flat band diagram and corresponding donor and acceptor state, respectively.

To further understand the effect of hydrogen and confirm the interpretation of the origin of conductivity, positron annihilation spectroscopy (PAS) measurements were carried out. PAS is a well-established technique to detect and characterize cation vacancies in semiconductors. Both Doppler Broadening of Positron Annihilation Spectroscopy (DBPAS) and Positron Annihilation Lifetime Spectroscopy (PALS) were employed. The details of the techniques and measurements are provided below.

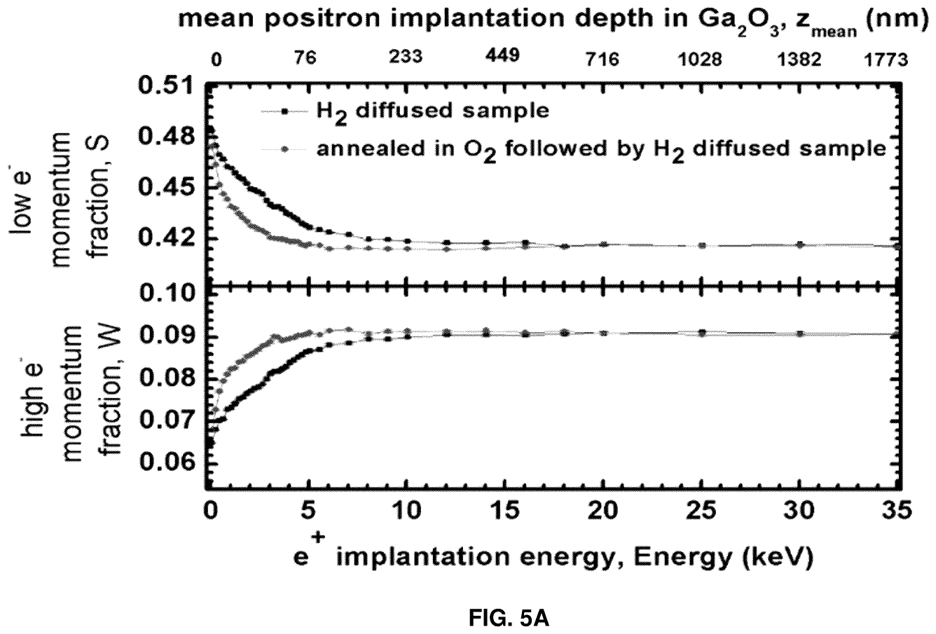

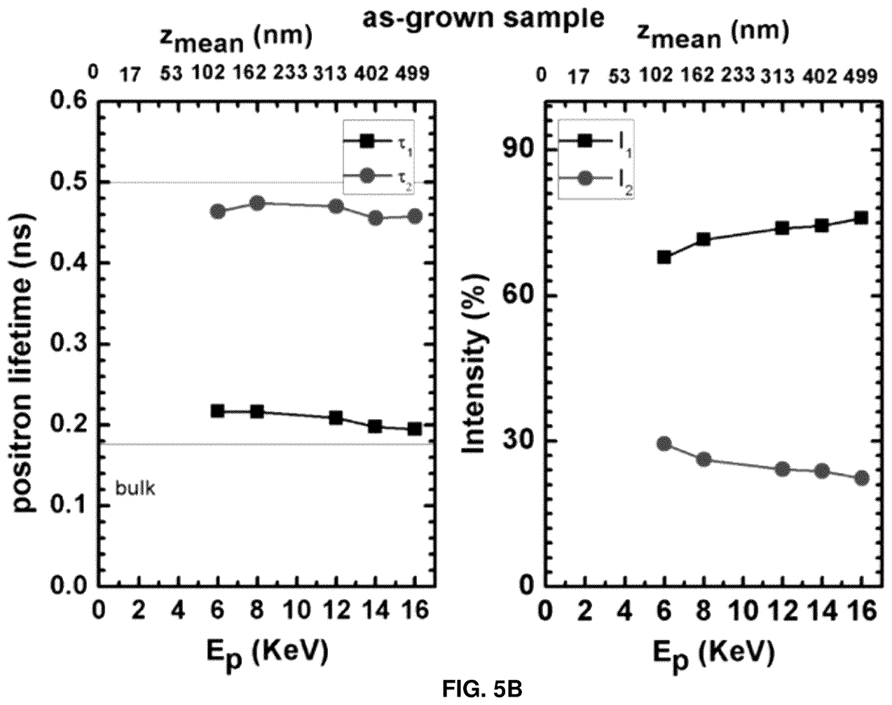

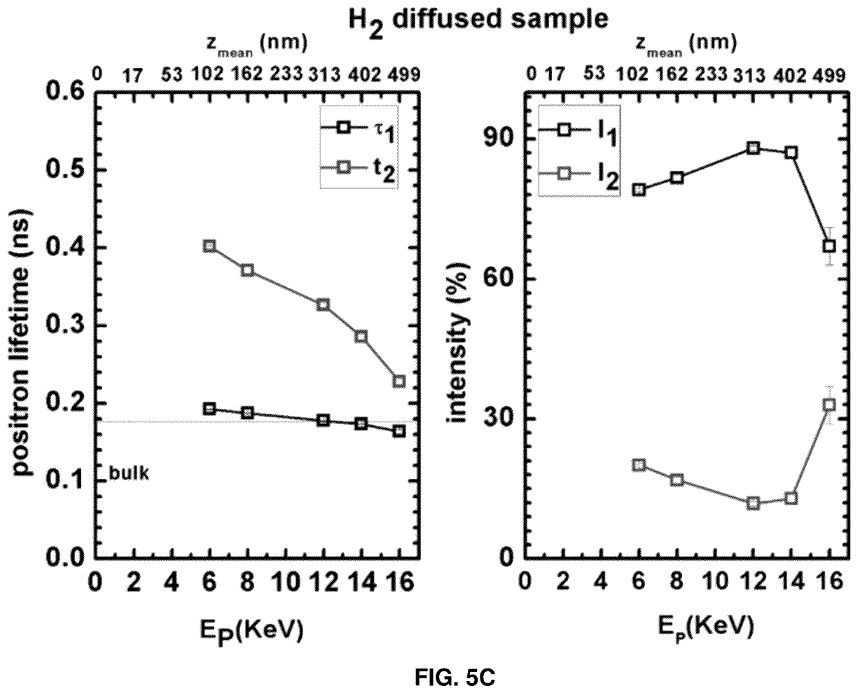

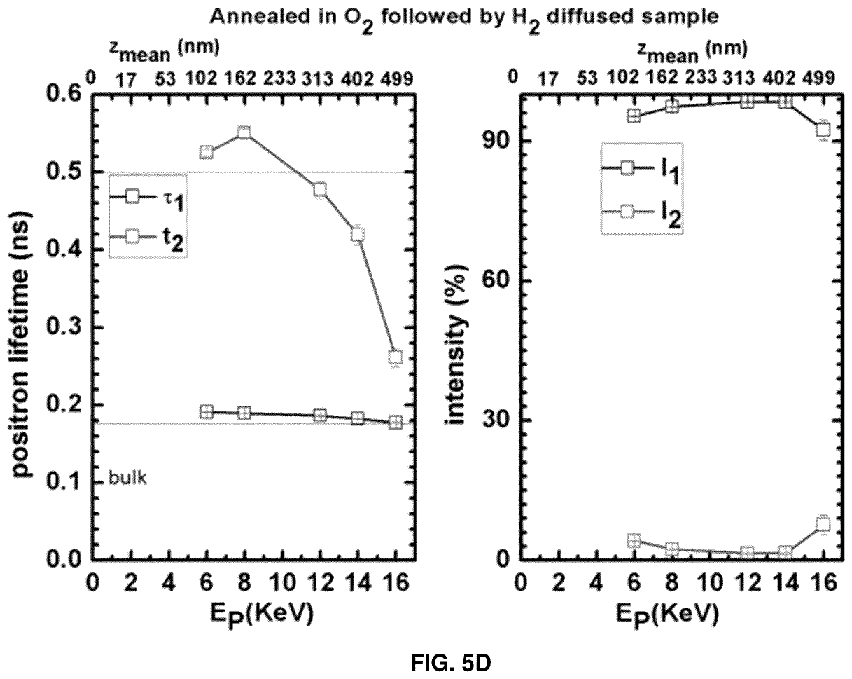

FIG. 5A displays the dependence of S- and W-parameters for the H₂-diffused and O₂-annealed followed by H₂-diffusion samples. The large values of S-parameter at the very beginning of the two curves are common in all DBPAS measurements, indicating the formation of positronium at the surface. The graph shows a large difference between the two samples in the first 500 nm with lower S values and higher W values for the sample annealed in O₂ followed by H₂, which exhibits high n-type conductivity. In DBPAS, the decrease in S-parameter is an indication for the suppression of positron trapping at cation or neutral vacancies. Thus, these measurements confirm the decrease of negatively charged and neutral vacancies in the O₂-annelead followed by H₂-diffusion sample. This is due to the filling of Ga-vacancies with more than three H-ions, leading to a positive charge state and the formation of a shallow donor, as indicated by the immense increase in n-type conductivity. This (H—V_{Ga})¹⁺ complex has a positive charge state and cannot trap positrons, leading to the substantial decrease in S-parameter. On the other hand, sole H₂-diffusion leads to partial filling of V_{Ga} with hydrogen, maintaining a negative charge state and leading to shallow acceptors, which imparts p-type conductivity. This (H—V_{Ga})¹⁻ complex is still an active positron trap which leads to a higher S-parameter.

Depth-resolved measurements of PALS revealed two major positron lifetime components for each sample. FIGS. 5B-5D show the lifetime components and their intensity as a function of depth for the as-grown sample, and the H₂ diffused, and O₂-annealed followed by H₂-diffused samples. A distinctive difference can be seen in the intensity and magnitude of the positron lifetime components among the three samples. The large second lifetime component τ2 indicates the presence of V_{Ga}-related defects with negative charge states. For as-grown Ga₂O₃, τ₂ is about 470 ps with about 25 to 30% intensity across the sample depth (FIG. 5B). After H₂-anneal, τ₂ was reduced to ˜320 ps indicating partial filling of V_{Ga} related defects with hydrogen while its intensity was reduced to about 13% (FIG. 5C) due to the decrease of positron trapping at these vacancies as a result of less negativity. After annealing in O₂ followed by H₂-diffusion, almost all positrons annihilate with lifetimes close to the bulk lifetime. The intensity of τ2 was reduced to about 1%, indicating almost complete absence of positron trapping at defects providing strong evidence for filling up V_{Ga} related defects with H₂ transforming them into donors with a positive charge state, which cannot trap positrons. Thus, DBPAS and PALS measurements explicitly confirm the interpretation for the origin of n-type and p-type conductivity.

In summary, by controlling H₂ diffusion and incorporation in the β-Ga₂O₃ lattice, the development of stable p-type and n-type Ga₂O₃ has been demonstrated. In the mean time, a simple method for doping and controlling the conductivity of wide band gap oxides has been developed with the realization of remarkable high carrier density and good mobility in oxide semiconductors, which is a significant challenge by common substitutional doping methods.

Hydrogen Incorporation Method and Transport Measurements

High quality β-Ga₂O₃ samples grown by Edge-defined Film-fed Growth (EFG) method were obtained from Tamura Inc., Japan. A number of samples (5 mm×5 mm×0.5 mm) were placed in a quartz ampoule with one open end that was connected to a vacuum pump to pump the air out and evacuate the ampoule. After that, the tube was filled with H₂ gas at 580 torr pressure. After filling the tube with hydrogen, the open end was properly sealed. The ampoule was placed in an oven where temperature can be precisely controlled. The temperature was increased in two steps up to the desired value and H₂ was allowed to diffuse into the crystal for 1 or 2 hours. A few other samples of the same dimensions were first annealed in oxygen flow at 950° C. and then hydrogen following the same procedure, while others were annealed first with gallium, then hydrogen following the same procedure.

Van der Pauw Hall-effect measurements were performed to determine the electrical transport properties of the samples. The measurements were carried out at room temperature (298 K) and at a constant magnetic field of 9300 G. Four indium contacts were made in a square arrangement on the surface of each sample and carefully adjusted to keep the contacts as small as possible. Current-voltage linearity was checked every time to make sure the contacts were good and resistivity did not vary more than 10% between different contact points.

Calculations of Donor/Acceptor Ionization Energy by Thermoluminescence Spectroscopy

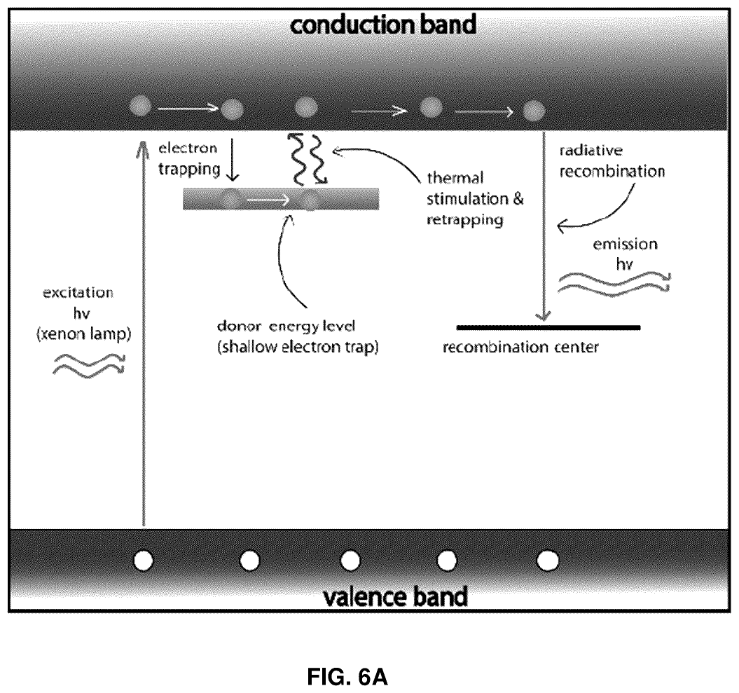

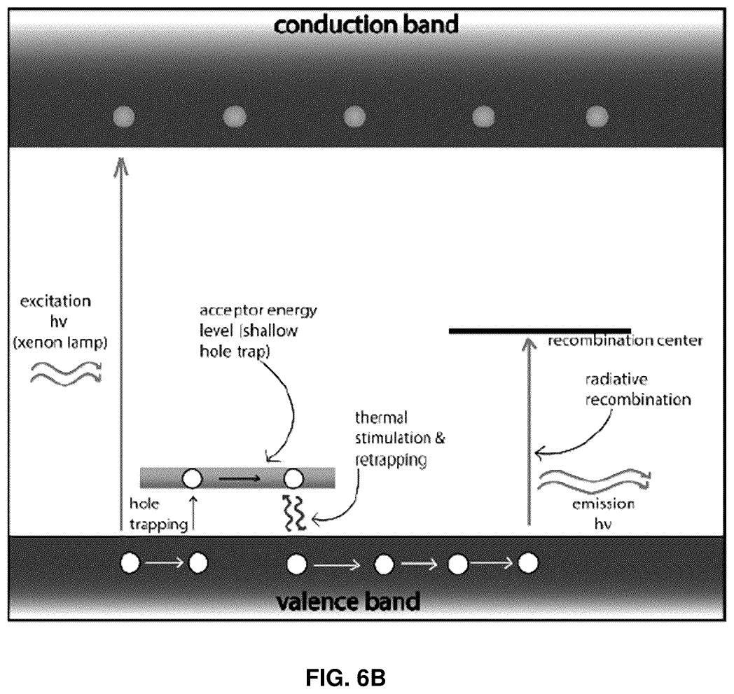

Thermoluminescence (TL) is the emission of light from materials upon thermal stimulation after irradiating the sample by ionizing radiation at low temperatures. It is a powerful technique to calculate the energy levels of defects that trap charge carriers (e.g., electrons/hole) at low temperature. The phenomena can be explained by energy band theory of solids. At lower temperatures, most of the charge carriers (e.g., electrons/holes) reside in the valence band in an ideal semiconductor. Electrons can be excited to the conduction band (holes to the valence band) upon excitation. Wide band gap materials often have structural defects that can trap charge carriers. Donor/acceptor states can also be thought of as defects that trap charge carriers at low temperatures. Thermal stimulation can release the electrons/holes from these traps where they transfer their energy to luminescence centers. A schematic diagram of the TL process is given in FIGS. 6A-6B.

TL measurements were performed using an in-house built spectrometer that records emission as a function of temperature and wavelength. The measurements were carried out from −190° C. to 250° C. The samples were first placed in a dark compartment and irradiated with UV light using a pulsed Xenon lamp at −190° C. for 30 min. Liquid nitrogen, a water pump, and a digital temperature regulator were used to precisely regulate the temperature. After irradiation, the temperature of the samples was set to increase at a constant rate (600° C./min) and the emission spectra were recorded from 200 to 800 nm at every 5 seconds. The glow curves, which represent the emission intensity as a function of temperature, were constructed from the integration of emission over wavelengths at each temperature.

Donor/acceptor ionization energy was calculated by initial rise method. Randall and Wilkins simplified the thermoluminescence model by assuming negligible re-trapping, linear heating rate, and formulated the well-known Randall-Wilkins first order expression for TL intensity:

$$I ( T ) = {n}_{0} \frac{s}{β} exp \{ - \frac{{E}_{D}}{kT} ) \times exp \{ - \frac{s}{β} {\int }_{{T}_{0}}^{T} exp \{ - \frac{{E}_{D}}{kT ′} \} {dT}^{′} \qquad ( 1 )$$

Here, s is the frequency factor and is considered as a constant in the simplified model, T is the absolute temperature, k is the Boltzman constant, ED is the donor/acceptor ionization energy, no is the total number of trapped electrons/holes at time t=0, and β is the constant heating rate. The symmetric shape of the peaks for the samples indicates second or higher order kinetics where significant re-trapping of charge carriers occurs after de-trapping from the traps. A similar equation was derived for the second order kinetics where significant re-trapping occurs:

$$I ( T ) = \frac{{n}_{0}^{2} s}{N β} \{ - \frac{{E}_{D}}{kT} ) \times {[ 1 + \frac{{n}_{0} s}{N β} {\int }_{{T}_{0}}^{T} exp \{ - \frac{{E}_{D}}{kT ′} \} {dT}^{′} ]}^{- 2} \qquad ( 2 )$$

Initially, intensity of glow peak is dominated by the first exponential half of equations (1) and (2), and the last half can be negligible. As a result, if ln(I) is plotted for the initial points of the glow peak, a straight line is obtained with the slope from which donor/acceptor ionization energy, ED, can be calculated. Linear fittings of ln(I) vs 1/T for n-type (FIG. 3A) and p-type (FIG. 3B) samples are shown in FIGS. 7A-7B, respectively. Donor ionization energy of R—Ga₂O₃ sample annealed in oxygen followed by hydrogen diffusion (FIG. 7A), and acceptor ionization energy of hydrogen diffused R—Ga₂O₃ sample (FIG. 7B) were found to be 20 meV and 42 meV, respectively.

Computation Methods for Calculating Hydrogen Binding Energy by Density Functional Theory (DFT)

Density functional theory, as implemented in the Vienna ab-initio Simulation Package (VASP), was used to examine hydrogen incorporation into a Ga vacancy. These calculations were performed on a 1×4×2 supercell of R—Ga₂O₃, containing a total of 160 atoms in the defect-free structure. A Γ-centered 2×2×2 Monkhorst-Pack k-point mesh was used to sample the Brillouin zone. The energy cutoff for the plane waves was 400 eV. Pseudopotentials based on the projector augmented wave method and the Perdew, Burke, and Ernzerhof (PBE) generalized gradient approximation (GGA) exchange-correlation functional were used. Generally, calculations were continued until the maximum component of the force on any atom was less than 0.02 eV/angstrom, with one exception (the charged Ga vacancy), where such a tight convergence was not possible. In this case, the maximum force was 0.024 eV/angstrom. Both monopole corrections (using a calculated dielectric constant of 4.16, which is a bit higher than previously reported values) and an alignment correction were applied to the energies. Instead of averaging the potential to perform the alignment correction, the density of states was simply shifted such that the deepest state in the material aligned across different structures, which has been shown to give similar corrections. In any case, the magnitude of this correction was no greater than 0.1 eV.

A Ga vacancy was created by removing a tetrahedrally-coordinated Ga ion from the cell, as this vacancy structure has been identified as being the more favorable. A net charge of −3 was imposed on the structure. Hydrogen ions with a charge of +1 were inserted into the resulting vacancy structure, leaving the total number of electrons in the system constant, but reducing the net charge of the cell. The resulting binding energy for each configuration was computed via the following relationship:

E_{b}=E([V_{Ga}NH]^{(-3+N)})+E(Bulk Ga²O³)−E(V_{Ga}³⁻)−NE(H⁺) (3)

where E([V_{Ga}NH]^{(-3+N)}) is the energy of the system with the Ga vacancy filled with N H+ ions, E(Bulk Ga₂O₃) is the energy of defect-free β-Ga₂O₃, E(V_{Ga}³⁻) is the energy of the isolated Ga vacancy in a 3− charge state, and E(H⁺) is the energy of an isolated 1+ H interstitial. With this definition, a negative energy indicates an exothermic or favorable reaction. A systematic search for the lowest energy H interstitial position was not performed, but multiple minimizations where the H was randomly displaced to find a reasonable structure were performed. The structure found here is one in which the H⁺ ion is bonded to one of the three-fold coordinated oxygen ions.

Positron Annihilation Lifetime Spectroscopy (PALS) and Doppler Broadening of Positron Annihilation Spectroscopy (DBPAS)

Doppler Broadening of Positron Annihilation Spectroscopy (DBPAS) measurements were carried out using a mono-energetic variable energy positron beam. Positrons were emitted from an intense 22 Na source and a tungsten moderator and accelerated to discrete energy values Eₚ in the range of Ep=0.05-35 keV. Such positron implantation energy, Ep, allows penetrating up to about 1.8 m in Ga₂O₃. Doppler broadened spectra representing positron annihilation distribution for each Eₚ were acquired using a single high-purity germanium detector with energy resolution of 1.09±0.01 keV at 511 keV. Doppler broadening spectroscopy analysis was carried out on the recorded 511 keV peak originating from electron-positron annihilation. The difference between electron momentum distributions is represented by a Doppler shift in the annihilation photons. The low electron momentum part of the 511 keV peak is characterized by the so-called S-parameter (shape parameter), which is defined as the number of annihilation events in the very middle of the peak, in an energy window of about 511±0.742 keV normalized to the total number of events. It reflects positron annihilation fraction with valence electrons. The high electron momentum part of the peak, on the other hand, is represented by the so-called W-parameter (wing parameter), defined as a number of annihilation events from a tail of the spectrum, in the energy windows of about 508-509 keV and about 513-514 keV normalized to the total number of events. It reflects positron annihilation fraction with core electrons. Positron trapping at defects leads to an increase of positron annihilation with valence electrons and S-parameter, and a decrease in positron annihilation with core electrons and W-parameter. In order for such analysis to be feasible, a large number of statistics should be acquired. Here, for each value of Eₚ, a spectrum for the 511 keV peak consisting of minimum 1-1.5×10⁵ total counts was acquired, and the S and W parameters were calculated at each Eₚ.

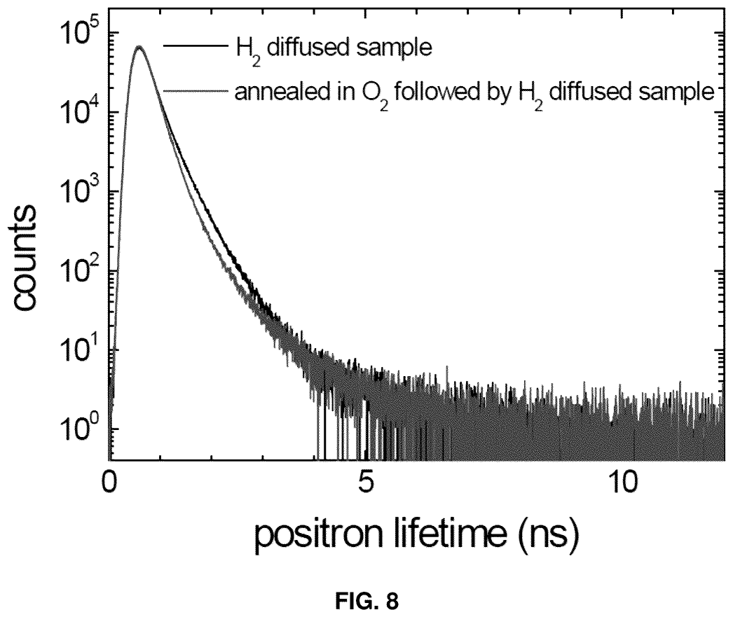

Positron annihilation lifetime spectroscopy (PALS) has been established as an effective method to probe cation vacancy related defects, distinguishing between their types and providing information about their concentrations. The positron lifetime experiments were performed at a pulsed mono-energetic positron spectroscopy beamline. The lifetime spectrum was measured at each positron energy Eₚ up to 16 keV. FIG. 8 shows the positron lifetime spectra obtained at Eₚ=6 keV for the two samples, annealed in H₂ and annealed in O₂ followed by H₂. A digital lifetime CrBr₃ scintillator detector with homemade software employing a SPDevices ADQ14DC-2X with 14 bit vertical resolution and 2GS/s horizontal resolution was used. It had been optimized for room-temperature measurements with a time resolution function of 205 ps. The resolution function required for spectrum analysis used two Gaussian functions with varied intensities depending on positron implantation energy, Eₚ, and appropriate relative shifts. All spectra contained at least 5·10⁶ counts. The positron lifetime spectra were analyzed as a sum of time-dependent exponential decays N(t)=ΣᵢIᵢ/τᵢ·exp(−t/τᵢ) convoluted with the Gaussian's functions describing the spectrometer timing resolution, using the non-linearly least-squared based package PALSfit fitting software. A Yttria-stabilized zirconia (YSZ) reference sample with well-defined single component positron lifetime, τ≈181 ps, was utilized as a correction spectrum to account for unwanted background by means of subtracting additional, not related to the sample positron lifetime, components. Positron lifetime components and their intensities calculated from this analysis give an indication about the type and density of defects, respectively.

Temperature Dependent Transport Properties, XRD Measurements, TSL Measurements, and PL Measurements

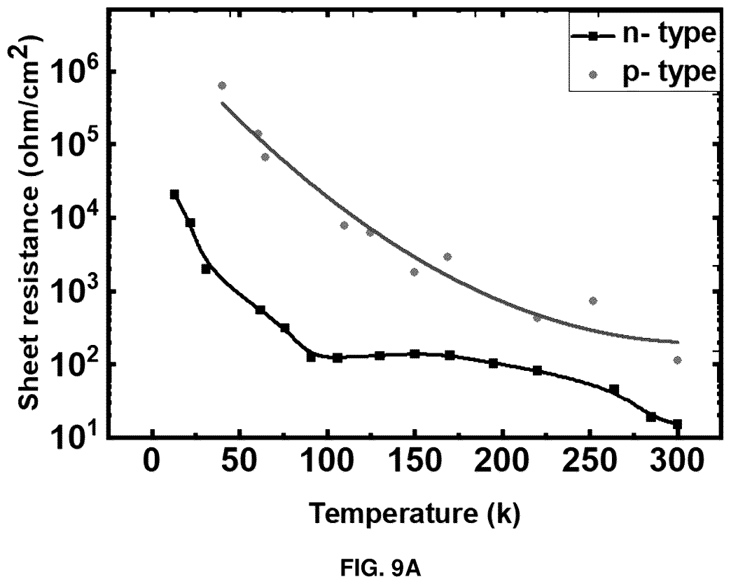

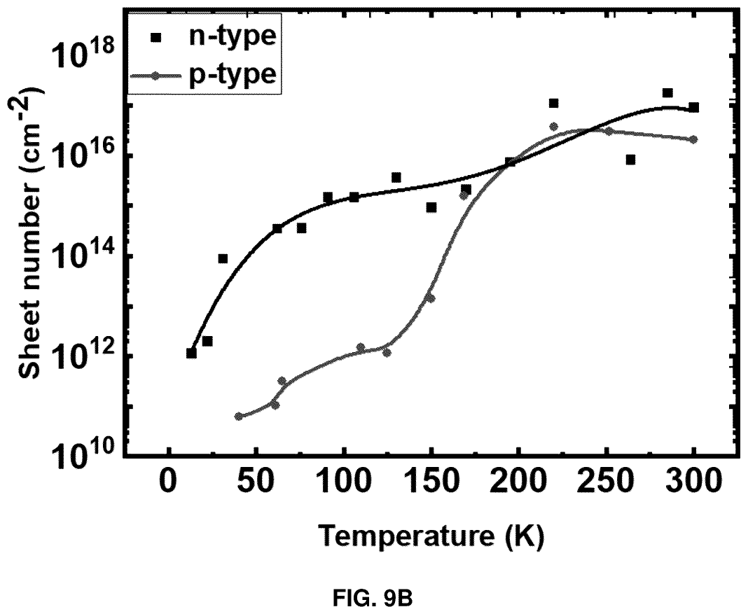

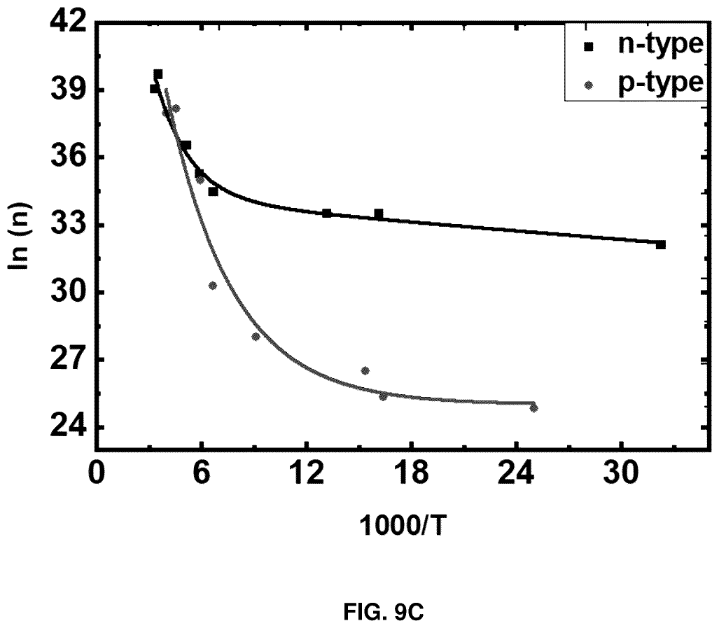

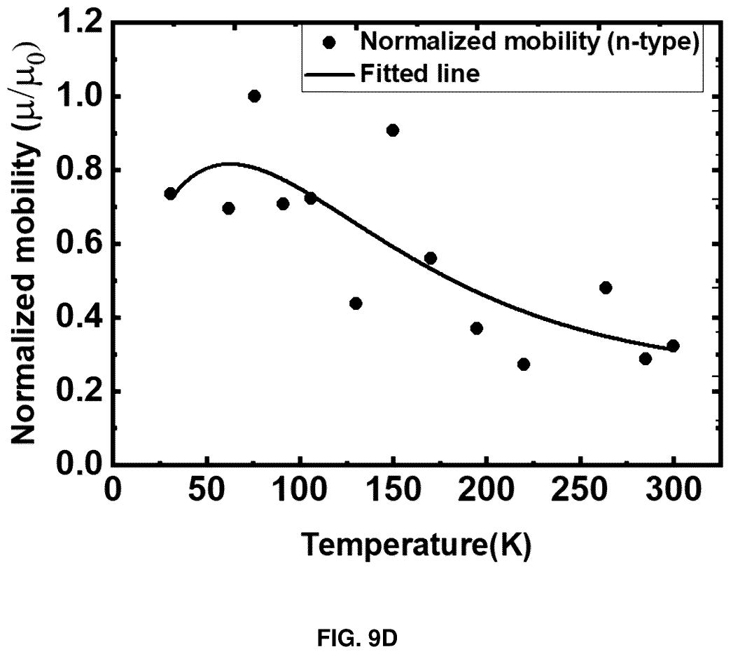

FIGS. 9A-9D show temperature dependent transport properties of the n-type and p-type H₂ treated p-Ga₂O₃ samples. FIG. 9A shows sheet resistance. FIG. 9B shows sheet number. FIG. 9C shows sheet number logarithm plotted as a function of 1000/T. FIG. 9D shows the dependence of n-type mobility on temperature. The mobility was found to be 100 cm²/VS at room temperature. It was normalized to the highest value at low temperature because of the noise in the cryostat system.

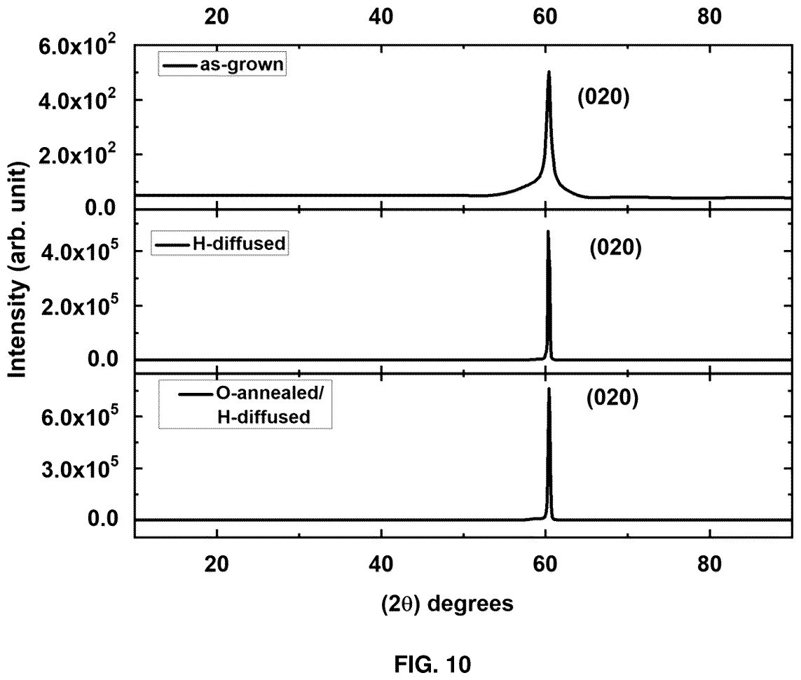

FIG. 10 shows X-ray diffraction (XRD) measurements of as-grown sample, H-diffused p-type sample, and O-annealed H-diffused n-type sample. The measurements show that H-diffusion or annealing did not affect the crystallinity and orientation of the samples.

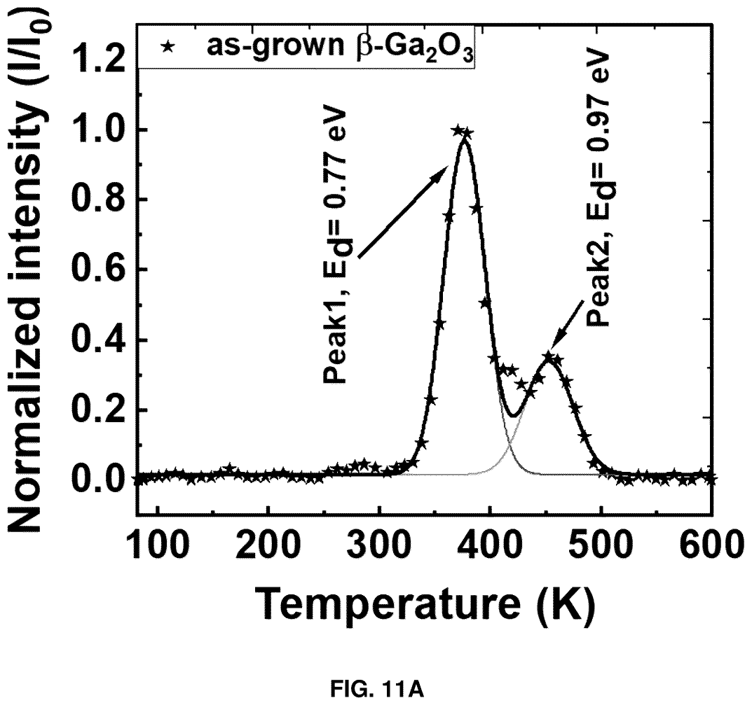

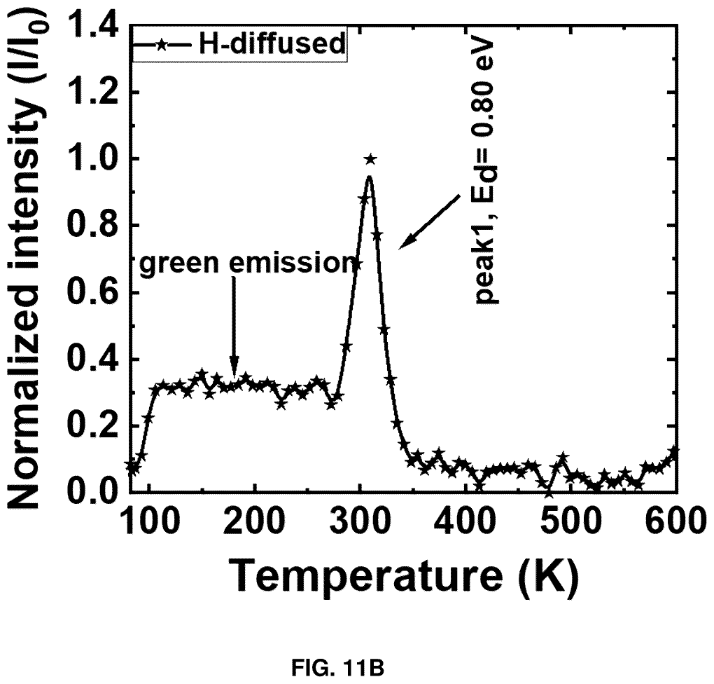

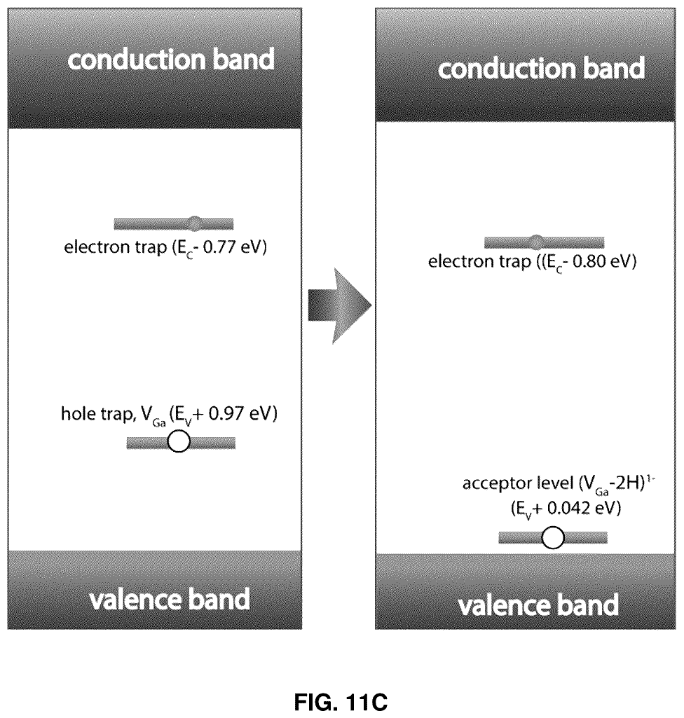

More thermal stimulated luminescence (TSL) measurements were performed at higher temperature to investigate the presence of deep traps in the samples. The energy levels of defects (traps) were calculated from the glow curves using the initial rise methods. FIGS. 11A-11B show TSL glow curves of the as-grown (FIG. 11A) and p-type H diffused (FIG. 11B) samples, showing the deep traps in the samples. FIG. 11C is a diagram illustrating the location of these levels in the band gaps. These measurements illustrate how hydrogen in Ga vacancy lower the energy level of Ga-vacancy, transforming it from deep acceptor to shallow acceptor. These measurements provide further confirmation on how p-type conductivity is induced by lowering the acceptor levels.

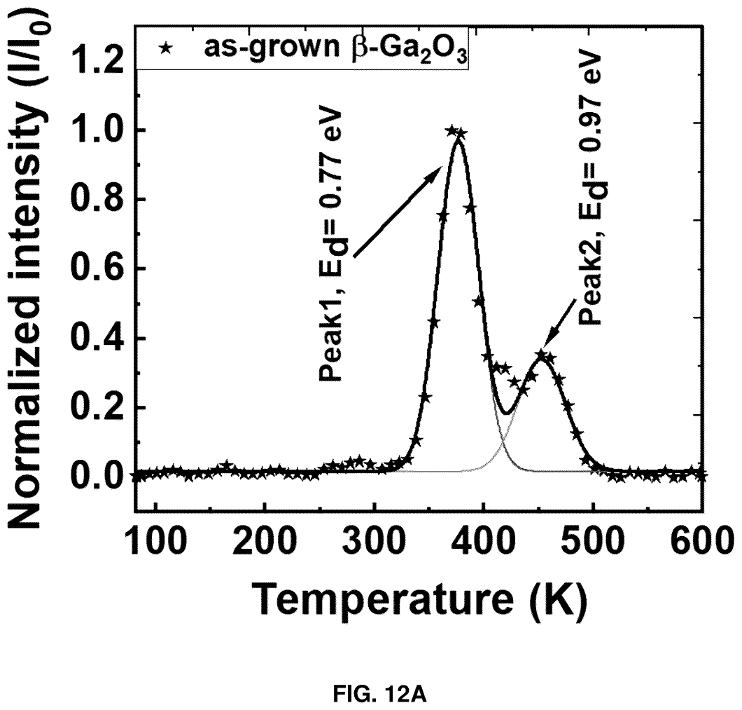

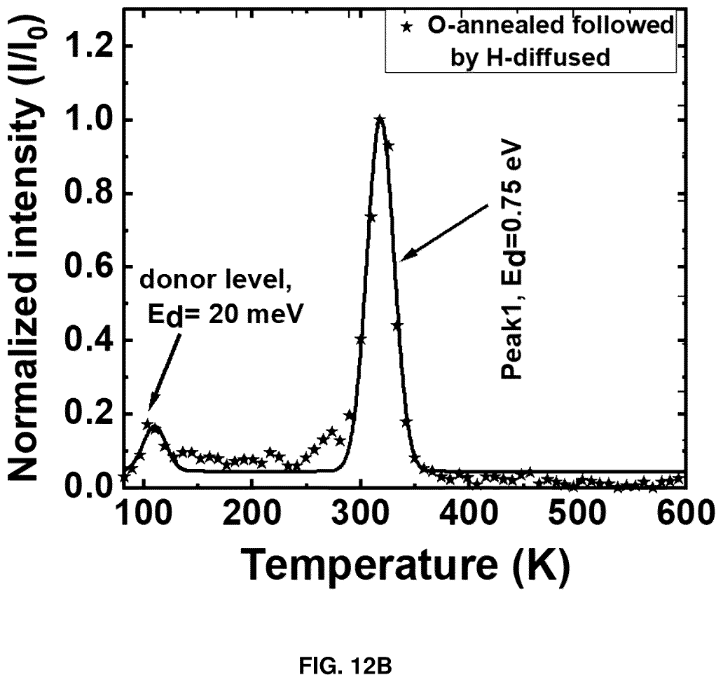

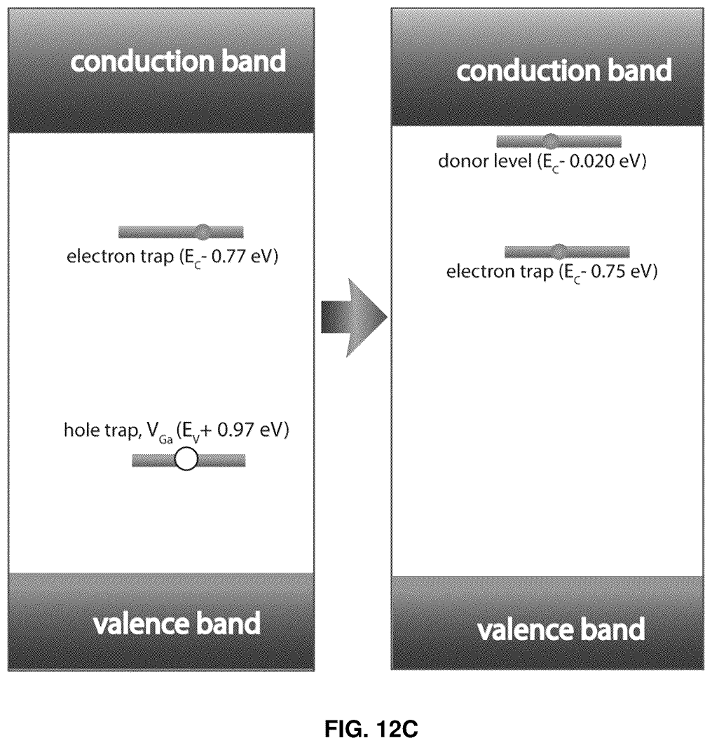

FIGS. 12A-12B show TSL glow curves of as-grown (FIG. 12A) and n-type O-annealed H-diffused (FIG. 12B) samples, showing the deep traps in the samples. FIG. 12C shows a diagram illustrating the locations of these levels in the band gap. These measurements illustrate how H-diffusion after O-annealing transfers the deep acceptor level to shallow donor.

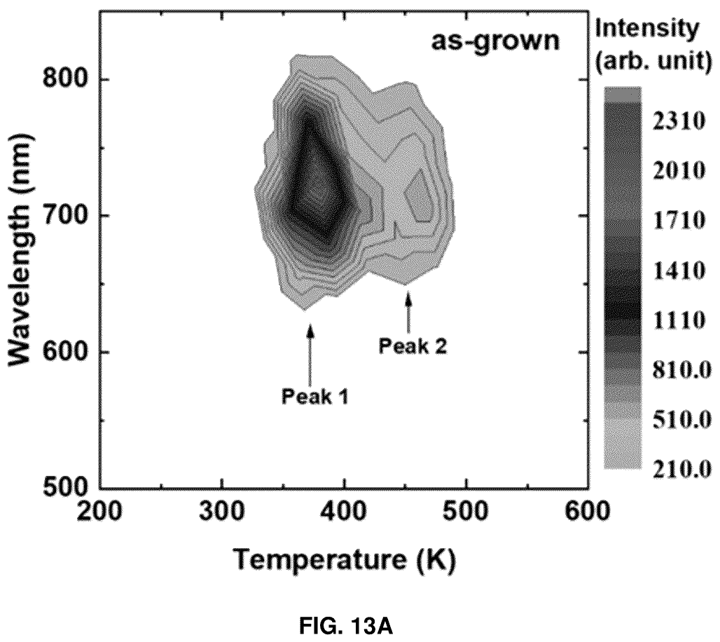

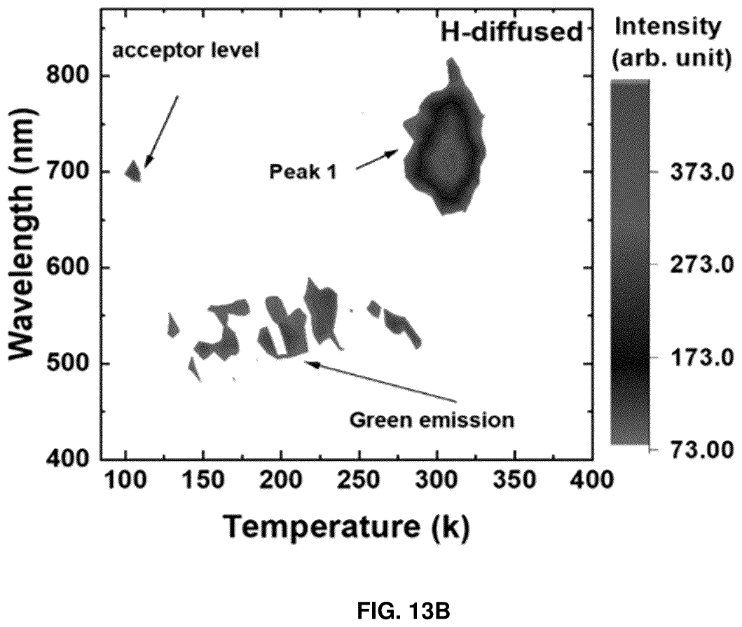

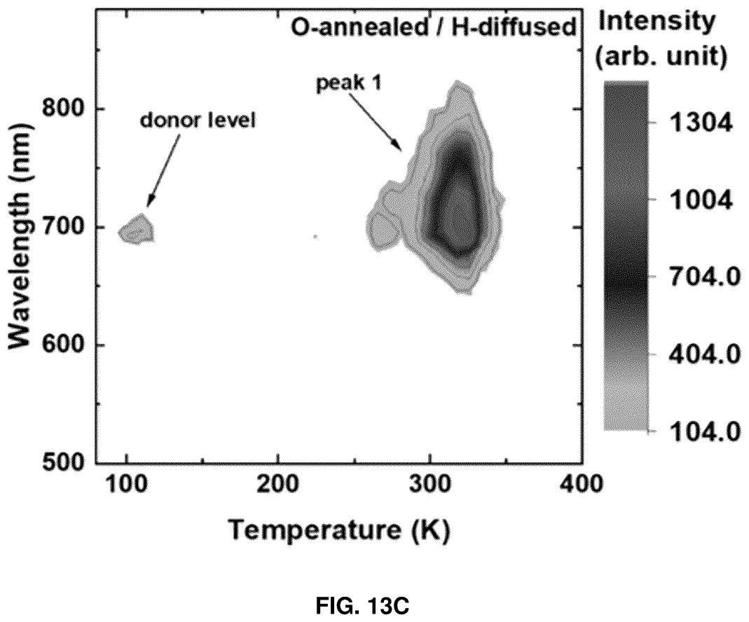

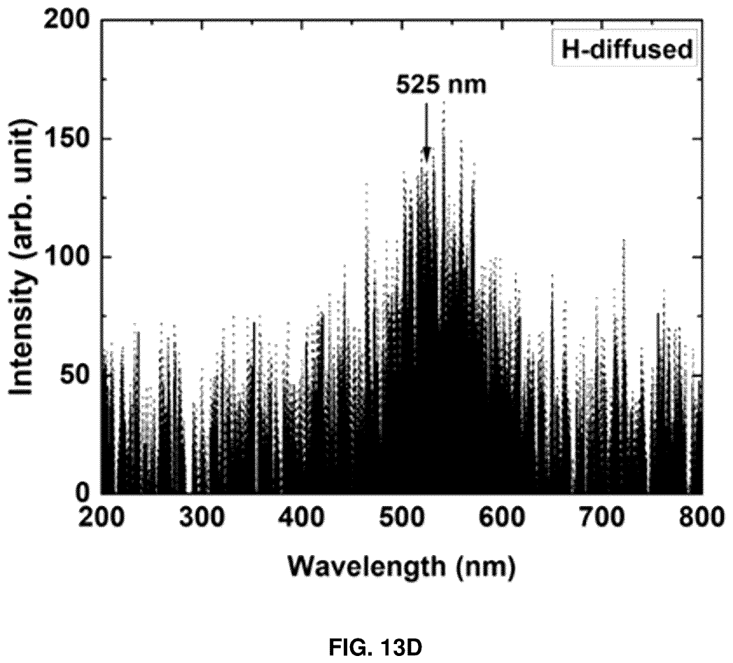

FIGS. 13A-13D show contour plots of as-grown (FIG. 13A), H-diffused (FIG. 13B), and O-annealed followed by H-diffused (FIG. 13C) samples where emission intensity is plotted as a function of temperature and wavelength. FIG. 13D shows green emission from a H-diffused p-type sample.

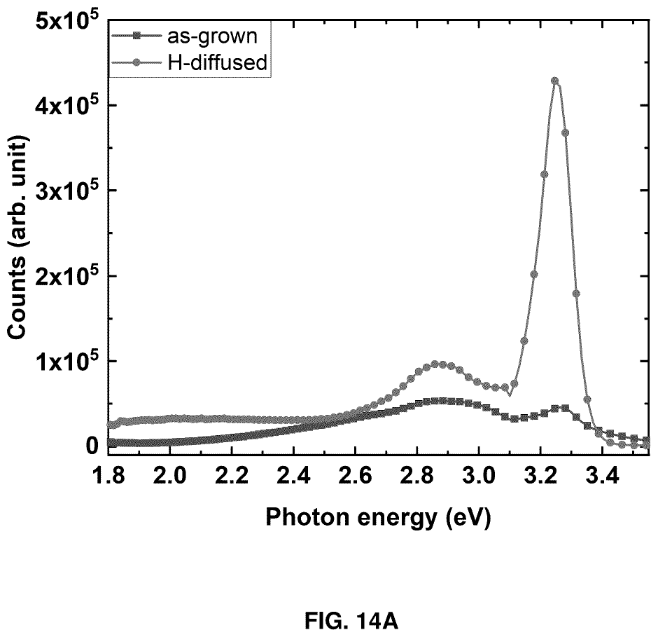

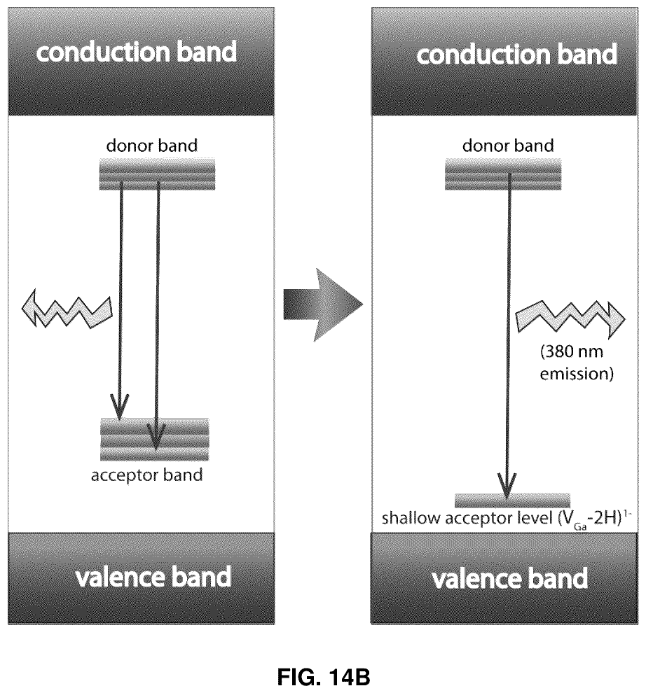

Photoluminescence (PL) measurements revealed strong UV emission at 380 nm (3.26 eV) in the p-type H-diffused samples. This emission is due to the formation of shallow acceptors. FIG. 14A shows PL emission of the as-grown and p-type H-diffused sample. FIG. 14B shows two diagrams; the diagram on the right illustrates the mechanism of the 380 nm UV emission, and the diagram on the left illustrates the mechanism of the broad emission (blue and green).

Certain embodiments of the compositions, devices, and methods disclosed herein are defined in the above examples. It should be understood that these examples, while indicating particular embodiments of the invention, are given by way of illustration only. From the above discussion and these examples, one skilled in the art can ascertain the essential characteristics of this disclosure, and without departing from the spirit and scope thereof, can make various changes and modifications to adapt the compositions, devices, and methods described herein to various usages and conditions. Various changes may be made and equivalents may be substituted for elements thereof without departing from the essential scope of the disclosure. In addition, many modifications may be made to adapt a particular situation or material to the teachings of the disclosure without departing from the essential scope thereof.

1. A composition comprising an oxide semiconductor material with a cation vacancy filled with hydrogen.

2. The composition of claim 1, the oxide semiconductor material comprising a (H—V_{Ca})¹⁻ complex, wherein Ca is the cation, and wherein the oxide semiconductor material has p-type conductivity.

3. The composition of claim 1, the oxide semiconductor material comprising a (H—V_{Ca})¹⁺ complex, wherein Ca is the cation, and wherein the oxide semiconductor material has n-type conductivity.

4. The composition of claim 1, wherein the oxide semiconductor comprises Ga₂O₃.

5. A composition comprising p-type Ga₂O₃.

6. The composition of claim 5, wherein the p-type Ga₂O₃ comprises hydrogen atoms as dopants.

7. The composition of claim 6, wherein the hydrogen atoms are in Ga vacancies in the p-type Ga₂O₃.

8. (canceled)

9. A The composition of claim 3, wherein the oxide semiconductor material comprises n-type Ga₂O₃.

10. The composition of claim 9, wherein the n-type Ga₂O₃ has a crystal structure having 4 hydrogen atoms in Ga vacancies.

11-12. (canceled)

13. A The composition of claim 9, wherein the n-type Ga₂O₃ has both of: a sheet carrier concentration of at least about 10¹⁶ cm², and a mobility of at least about 100 cm²/VS at room temperature.

14. (canceled)

15. The composition of claim 9, wherein the n-type Ga₂O₃ is a thin film having a thickness ranging from about 100 nm to about 900 nm.

16. The composition of claim 9, wherein the n-type Ga₂O₃ has a resistivity of about 10⁻⁴ Ω·cm.

17-24. (canceled)

25. A method of bipolar doping, the method comprising either:
partially filling cation vacancies in an oxide semiconductor material with hydrogen, thereby lowering their acceptor states to act as shallow acceptors, so as to dope the oxide semiconductor material p-type; or
filling the cation vacancies with hydrogen plus an extra H-ion, so as to dope the oxide semiconductor material n-type.

26. The method of claim 25 for doping an oxide semiconductor material p-type, the method comprising:
placing an oxide semiconductor material in a sealed system;
evacuating air from the sealed system;
introducing hydrogen gas into the sealed system; and
annealing the oxide semiconductor material in the sealed system at an elevated temperature for a period of time to allow the hydrogen gas to diffuse into the oxide semiconductor material and thereby dope the oxide semiconductor material p-type.

27-35. (canceled)

36. The method of claim 26, wherein the oxide semiconductor material comprises Ga₂O₃.

37. The method of claim 26, wherein the oxide semiconductor material comprises Ga₂O₃, the elevated temperature is about 950° C., the period of time is about 2 hours, and the sealed system is at a pressure of about 580 torr during the annealing.

38. A The method of claim 25 for doping an oxide semiconductor material n-type, the method comprising:
annealing an oxide semiconductor material in air for a first period of time at a first temperature;
placing the oxide semiconductor material in a sealed system;
evacuating air from the sealed system;
introducing hydrogen gas into the sealed system; and
annealing the oxide semiconductor material in the sealed system at a second elevated temperature for a second period of time to allow the hydrogen gas to diffuse into the oxide semiconductor material and thereby dope the oxide semiconductor material n-type.

39-52. (canceled)

53. The method of claim 38, wherein the oxide semiconductor material comprises Ga₂O₃.

54. The method of claim 38, wherein the oxide semiconductor material comprises Ga₂O₃, the first period of time is about 2 hours, the first temperature is about 950° C., the second period of time is about 2 hours, and the second temperature is about 950° C., and the sealed system is at a pressure of about 580 torr during the annealing.

55. The method of claim 25, wherein hydrogen plasma is used in a plasma reactor to either partially fill cation vacancies in the oxide semiconductor material with hydrogen or fill the cation vacancies with hydrogen plus an extra H-ion.

56-57. (canceled)
